(19) United States
(12) Patent Application Publication
(10) Pub. No.: US 2025/0212575 A1
(43) Pub. Date: Jun. 26, 2025

(54) LIGHT-EMITTING ELEMENT, AND METHOD AND DEVICE FOR MANUFACTURING SAME

(71) Applicant: KYOCERA Corporation, Kyoto-shi, Kyoto (JP)

(72) Inventors: Yoshinobu KAWAGUCHI, Kyoto-shi (JP); Takeshi KAMIKAWA, Kyoto-shi (JP); Kentaro MURAKAWA, Kyoto-shi (JP)

(73) Assignee: KYOCERA Corporation, Kyoto-shi, Kyoto (JP)

(21) Appl. No.: 18/852,020

(22) PCT Filed: Mar. 27, 2023
(86) PCT No.: PCT/JP2023/012194

§ 371 Date: Sep. 27, 2024

(30) Foreign Application Priority Data
Mar. 28, 2022 (JP) 2022-052493

(51) Int. Cl. H10H 20/857; H01S 5/02315; H01S 5/0237; H01S 5/22; H01S 5/30; H10H 20/01; H10H 20/819; H10H 20/825; H10H 20/85

(52) U.S. Cl. CPC H10H 20/857; H01S 5/02315; H01S 5/0237; H01S 5/22; H01S 5/3013; H10H 20/0364; H10H 20/819; H10H 20/825; H10H 20/8508

(57) ABSTRACT

A light-emitting element includes: a light emitter including a first type semiconductor portion having a first side surface and first type conductivity, an active portion positioned below the first type semiconductor portion, and a second type semiconductor portion having second type conductivity and reaching laterally the first type semiconductor portion from below the active portion; (ii) a conductive bonding material; and (iii) a support body positioned below the light emitter and supporting the light emitter via the conductive bonding material and thus the first type semiconductor portion is positioned higher than the active portion.

### TECHNICAL FIELD

The present disclosure relates to a light-emitting element and the like.

### BACKGROUND OF INVENTION

In general, a light-emitting element such as a light-emitting diode may be manufactured by mounting a singulated light emitter (sometimes called a die) on a support body such as a substrate. For example, a known mounting method includes bonding (so-called flip chip bonding) an electrode on a surface side of a light emitter and an electrode of a support body via a conductive bonding material such as solder, the electrode on the surface side of the light emitter being formed by layering a semiconductor layer on a growth substrate (see Patent Document 1). Such a mounting method is also called “junction-down mounting”.

### CITATION LIST

### Patent Literature

Patent Document 1: JP 2012-151182 A

### SUMMARY

In one aspect of the present disclosure, a light-emitting element includes: a light emitter including a first type semiconductor portion having a first side surface and first type conductivity, an active portion positioned below the first type semiconductor portion, and a second type semiconductor portion having second type conductivity and reaching laterally the first type semiconductor portion from below the active portion; a conductive bonding material; and a support body positioned below the light emitter and supporting the light emitter via the conductive bonding material and thus the first type semiconductor portion is positioned higher than the active portion.

In one aspect of the present disclosure, a method for manufacturing a light-emitting element includes: preparing a semiconductor substrate in which a first type semiconductor portion having a first side surface is formed on a base substrate; forming an active portion higher than the first type semiconductor portion; forming a second type semiconductor portion reaching laterally the first type semiconductor portion from above the active portion; preparing a support substrate; and bonding a light emitter including at least a part of each of the first type semiconductor portion, the active portion, and the second type semiconductor portion to the support substrate via a conductive bonding material, and thus the first type semiconductor portion is positioned higher than the active portion.

In one aspect of the present disclosure, a method for manufacturing a light-emitting element includes: preparing a semiconductor substrate in which a first type semiconductor portion, an active portion, and a second type semiconductor portion are formed in this order on a base substrate; forming an insulating film on a side surface of at least one selected from the group consisting of the first type semiconductor portion, the active portion, and the second type semiconductor portion; preparing a support substrate; and bonding a light emitter including at least a part of each of the first type semiconductor portion, the active portion, and the second type semiconductor portion to the support substrate via a conductive bonding material, and thus the first type semiconductor portion is positioned higher than the active portion.

### BRIEF DESCRIPTION OF THE DRAWINGS

FIG. 1 is a cross-sectional view schematically illustrating a configuration of a light-emitting element in one embodiment of the present disclosure.

FIG. 2 is a perspective view for schematically describing an example of a process of junction-down mounting a light emitter onto a support body.

FIG. 3 is a cross-sectional view illustrating an example of a method for manufacturing a light-emitting element in the embodiment of the present disclosure.

FIG. 4 is a plan view schematically illustrating an example of the method for manufacturing a light-emitting element in the embodiment of the present disclosure.

FIG. 5 is a flowchart showing an example of the method for manufacturing a light-emitting element in the embodiment of the present disclosure.

FIG. 6 is a block diagram illustrating an example of a device for manufacturing a light-emitting element in the embodiment of the present disclosure.

FIG. 7A is a cross-sectional view illustrating a light-emitting element in another configuration example of the embodiment of the present disclosure.

FIG. 7B is a cross-sectional view illustrating a light-emitting element in another configuration example of the embodiment of the present disclosure.

FIG. 7C is a cross-sectional view illustrating a light-emitting element in another configuration example of the embodiment of the present disclosure.

FIG. 8 is a perspective view illustrating a configuration of a light emitter in Example 1.

FIG. 9 is a perspective view illustrating a configuration of an optical resonator.

FIG. 10A is a plan view illustrating a configuration of an active portion.

FIG. 10B is a plan view illustrating a configuration of an active portion.

FIG. 11 is a cross-sectional view illustrating a configuration of the light emitter in Example 1.

FIG. 12 is a flowchart schematically showing a method for manufacturing a light-emitting element in Example 1.

FIG. 13 is a plan view schematically illustrating a method for manufacturing a light emitter included in the light-emitting element in Example 1.

FIG. 14 is a cross-sectional view schematically illustrating a method for manufacturing the light-emitting element in Example 1.

FIG. 15 is a cross-sectional view schematically illustrating a method for manufacturing the light-emitting element in Example 1.

FIG. 16 is a cross-sectional view illustrating a configuration example of a template substrate.

FIG. 17 is a plan view illustrating an example of a configuration of a support substrate.

FIG. 18 is a perspective view schematically illustrating a light-emitting substrate in which a plurality of light emitters is bonded to a support substrate.

FIG. 19 is a perspective view illustrating an example of a light-emitting substrate having a bar shape after division.

FIG. 20 is a perspective view illustrating a configuration of the light-emitting element in Example 1.

FIG. 21 is a cross-sectional view illustrating a configuration of the light-emitting element in Example 1.

FIG. 22 is a perspective view illustrating a configuration of a light-emitting element in another example of Example 1.

FIG. 23 is a cross-sectional view illustrating a configuration of the light-emitting element in another example of Example 1.

FIG. 24 is a cross-sectional view schematically illustrating a method for manufacturing the light-emitting element in another example of Example 1.

FIG. 25 is a flowchart schematically showing a method for manufacturing a light-emitting element in Example 2.

FIG. 26 is a cross-sectional view schematically illustrating a method for manufacturing the light-emitting element in Example 2.

FIG. 27 is a plan view schematically illustrating a method for manufacturing the light-emitting element in Example 2.

FIG. 28 is a plan view schematically illustrating a method for manufacturing a light-emitting element in another example of Example 2.

FIG. 29 is a cross-sectional view illustrating an example of lateral growth of a base semiconductor portion.

FIG. 30 is a cross-sectional view schematically illustrating a method for manufacturing a light-emitting element in Example 3.

FIG. 31 is a flowchart schematically showing a method for manufacturing a light-emitting element in Example 4.

FIG. 32 is a cross-sectional view schematically illustrating a method for manufacturing the light-emitting element in Example 4.

FIG. 33 is a cross-sectional view schematically illustrating a method for manufacturing the light-emitting element in Example 4.

FIG. 34 is a perspective view illustrating a configuration of a light emitter in Example 5.

FIG. 35A is a partial cross-sectional view of the light emitter in Example 5.

FIG. 35B is a partial plan view of the light emitter in Example 5.

FIG. 36 is a plan view schematically illustrating a method for manufacturing a light-emitting element in Example 5.

FIG. 37 is a plan view schematically illustrating a method for manufacturing a light-emitting element in another example of Example 5.

FIG. 38 is a plan view schematically illustrating a method for manufacturing a light-emitting element in Example 6.

### DESCRIPTION OF EMBODIMENTS

An embodiment of the present disclosure will be described below with reference to the accompanying drawings. Note that the following description is for better understanding of the gist of the present disclosure and does not limit the present disclosure unless otherwise specified. Unless otherwise specified in the present description, “A to B” representing a numerical value range means “equal to or greater than A and equal to or less than B”. Shapes and dimensions (length, width, and the like) of configurations illustrated in each of the drawings in the present application do not necessarily reflect actual shapes and dimensions, and are appropriately changed for clarification and simplification of the drawings. In other words, in the drawings, the size and the like of each member may be appropriately exaggerated.

### Light-Emitting Element

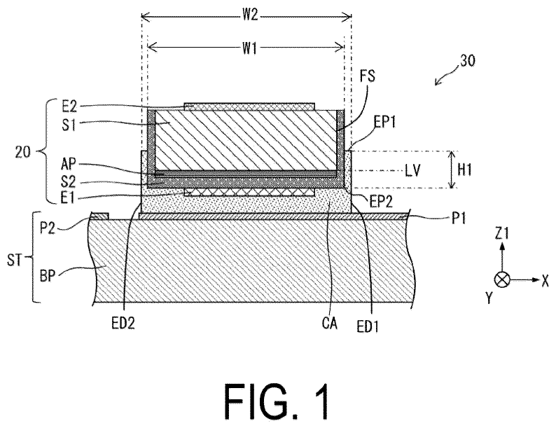

FIG. 1 is a cross-sectional view schematically illustrating the configuration of a light-emitting element in one embodiment of the present disclosure. As illustrated in FIG. 1, a light-emitting element 30 in the present embodiment includes a light emitter 20, a bonding material (conductive bonding material) CA having conductivity, and a support body ST (e.g., a submount) supporting the light emitter 20 via the bonding material CA.

The light emitter 20 includes (i) a first type semiconductor portion S1 having a first side surface FS and having first type conductivity, (ii) an active portion AP positioned below the first type semiconductor portion S1, and (iii) a second type semiconductor portion S2 having second type conductivity and reaching laterally the first type semiconductor portion S1 from below the active portion AP. Here, a direction from the light emitter 20 to the support body ST is defined as a downward direction (negative side in the Z1-axis direction). The support body ST is positioned below the light emitter 20, and supports the light emitter 20 via the bonding material CA, and thus the first type semiconductor portion S1 is positioned higher than the active portion AP.

The first type semiconductor portion S1 may be a first type semiconductor portion layer, the second type semiconductor portion S2 may be a second type semiconductor portion layer, and the active portion AP may be an active layer. The light emitter 20 may be, for example, a semiconductor laser diode (end surface emitting or surface emitting laser diode) or a light-emitting diode. The first type semiconductor portion S1 may have n-type conductivity, and the second type semiconductor portion S2 may have p-type conductivity. The present invention is not limited to this, and the first type semiconductor portion S1 may have p-type conductivity, and the second type semiconductor portion S2 may have n-type conductivity.

The first type semiconductor portion S1 and the second type semiconductor portion S2 may include a nitride semiconductor (e.g., a GaN-based semiconductor). The nitride semiconductor may be expressed by, for example, AlxGayInzN (0≤x≤1; 0≤y≤1; 0≤z≤1; x+y+z=1). Specific examples of the nitride semiconductor may include a GaN-based semiconductor, aluminum nitride (AlN), indium aluminum nitride (InAlN), and indium nitride (InN). The GaN-based semiconductor is a semiconductor containing gallium atoms (Ga) and nitrogen atoms (N). Typical examples of the GaN-based semiconductor may include GaN, AlGaN, AlGaInN, and InGaN.

The first type semiconductor portion S1 may include a non-doped (i-type) semiconductor. The first type semiconductor portion S1 may include a doped type semiconductor. A part in contact with the active portion AP in the first type semiconductor portion S1 may be an n-type semiconductor portion containing a donor. The second type semiconductor portion S2 may include a non-doped (i-type) semiconductor. For example, a part in contact with the active portion AP in the second type semiconductor portion S2 may be a non-doped (i-type) semiconductor.

A direction in which the first type semiconductor portion S1, the active portion AP, and the second type semiconductor portion S2 of the light emitter 20 are layered between the first type semiconductor portion S1 and the support body ST is defined as a Z1-axis direction. The thickness in the Z1-axis direction of the first type semiconductor portion S1 is larger than the thickness in the Z1-axis direction the second type semiconductor portion S2. The first type semiconductor portion S1 may include a crystal growth substrate, and in this case, the thickness in the Z1-axis direction of the first type semiconductor portion S1 is significantly larger than the thickness in the Z1-axis direction the second type semiconductor portion S2.

In the light-emitting element 30 in the present embodiment, the light emitter 20 (die) having a double-sided electrode structure is junction-down mounted (face-down mounted) on the support body ST (mounting substrate or the like). The junction-down mounting is a type in which the light emitter 20 is mounted on the support body ST with the active portion AP being positioned between the support body ST and the first type semiconductor portion S1. In general, the junction-down mounting has an advantage that heat dissipation can be enhanced. This is because the active portion AP considered to be a heat generator can be brought close to the support body ST also functioning as a heat dissipation member.

The light emitter 20 may include a first electrode E1 positioned below the second type semiconductor portion S2 and a second electrode E2 positioned above the first type semiconductor portion S1. The support body ST may include base portion BP, and a first pad P1 and a second pad P2 positioned above the base portion BP. The base portion BP may be a body (e.g., a substrate) of the support body ST. The first pad P1 and the first electrode E1 may be electrically connected to each other via the bonding material CA. The second pad P2 and the second electrode E2 may be electrically connected to each other by a wire, a conductive film, or the like (not illustrated).

The first side surface FS of the first type semiconductor portion S1 may be one of two side surfaces facing each other in the width direction (X-axis direction) of the first type semiconductor portion S1. The width direction (X-axis direction) of the first type semiconductor portion S1 may be an a-axis direction of a nitride semiconductor crystal. When the light emitter 20 has a double-sided electrode structure, the first side surface FS may be a side surface farther from the second pad P2 among the two side surfaces facing each other in the X-axis direction in the first type semiconductor portion S1. The second type semiconductor portion S2 may be smaller in thickness than the first type semiconductor portion S1. At least a part of the second type semiconductor portion S2 may be in contact with the first side surface FS.

The bonding material CA may have fluidity and may go up along the second type semiconductor portion S2 positioned laterally on the first side surface FS. The light-emitting element 30 is not limited to the example illustrated in FIG. 1, and the bonding material CA need not go up along the second type semiconductor portion S2.

An end on the positive side in the Z1-axis direction (the side far from the support body ST) of the bonding material CA going up along the second type semiconductor portion S2 is called EP1. In the cross section orthogonal to the Y-axis direction as illustrated in FIG. 1, an end point on the first side surface FS side of the lower (negative side in the Z1-axis direction) surface of the second type semiconductor portion S2 is called EP2. With reference to the position of the end EP2 in the Z1-axis direction, the position of the end EP1 higher than the end EP2 is called a go-up height H1 of the bonding material CA.

In the light-emitting element 30 in the present embodiment, the go-up height H1 may exceed a lower surface level LV of the first type semiconductor portion S1. The lower surface level LV corresponds to the position of a boundary between the first type semiconductor portion S1 and the active portion AP in the Z1-axis direction.

Viewing the light-emitting element 30 along the Z1-axis direction corresponding to the layering direction of the first type semiconductor portion S1 and the active portion AP can be called “plan view”. In plan view, two ends of the bonding material CA in the width direction (X-axis direction) of the light emitter 20 are called an edge ED1 and an edge ED2, respectively. The edge ED1 is an end on the first side surface FS side of the bonding material CA. The light-emitting element 30 may have a part of the edge ED1 and/or a part of the edge ED2 protruding from the light emitter 20 in plan view. In the light-emitting element 30 in the present embodiment, a width W2 of the bonding material CA, which is the distance between the edge ED1 and the edge ED2 in the X-axis direction, may be larger than a width W1 in the X-axis direction of the light emitter 20.

The light-emitting element 30 in the present embodiment will be described in more detail together with the schematic description of the knowledge of the present disclosure as follows.

In general, for example, an end surface emitting laser diode (hereinafter, laser element), which is one type of light-emitting element, may be formed as follows. First, various semiconductor layers are layered on a growth substrate (e.g., a substrate including an n-type semiconductor portion) to form a ridge structure, an electrode, and the like. Thus, a laser wafer having a device structure is prepared. For example, after the growth substrate is polished and thinned, the laser wafer is cleaved (primary cleavage), thereby forming a laser bar having an elongated cuboid shape. Next, after a resonator end surface of the laser bar is coated, the laser bar is cleaved (secondary cleavage) to be divided. Thus, a laser body (light emitter) is formed. Thereafter, the laser body is mounted on a submount to manufacture a laser element.

The following can be said for the known laser element manufactured by the general method as described above. Describing using the member names and reference signs of the light-emitting element 30 of the present embodiment, in the known laser element, the side surface in the width direction of the laser body is formed by split (cleavage) of the laser bar. In this case, the first side surface FS of the laser body is exposed. Therefore, when the bonding material CA goes up and comes into contact with the first side surface FS, a short circuit can occur between the first type semiconductor portion S1 and the first electrode E1. This is more likely to occur when the laser body is junction-down mounted on the support body ST. This is because the distance between the lower surface level LV of the first type semiconductor portion S1 and the support body ST decreases, and as a result, the go-up height H1 of the bonding material CA easily exceeds the lower surface level LV.

For such the problem described above, for example, known measures may be taken, such as greatly widening the width of the laser body than the width of the bonding material CA or narrowing the width of the bonding material CA or the first electrode E1. However, when the laser body is downsized, the narrower the width of the bonding material CA, the higher the possibility of an occurrence of a bonding failure between the laser body and the submount. Therefore, there is a limit in narrowing the width of the bonding material CA. Even if the width of the bonding material CA or the first electrode E1 is narrowed, the bonding material CA is deformed toward the side surface direction of the laser body at the time of junction-down mounting. This is because the bonding material CA is pressed and deformed when the laser body and the support body ST are bonded by applying a load. As a result, there is a possibility that the bonding material CA goes up the side surface of the laser body (wraps around the side surface of the laser body).

Alternatively, with the junction-up mounting, since the thickness of the first type semiconductor portion S1 is relatively thick, a p-n short circuit is relatively less likely to occur even if the bonding material CA goes up. However, such measures cannot be applied when it is assumed that the junction-down mounting is performed as in the light-emitting element 30 in the present embodiment.

It is theoretically conceivable to form an insulating film protecting the first side surface FS with respect to the known laser body after the laser bar is split. However, it is very difficult in terms of process to collectively form an insulating film on a large number of laser bodies to cover the first side surface FS without covering the electrode of the laser body.

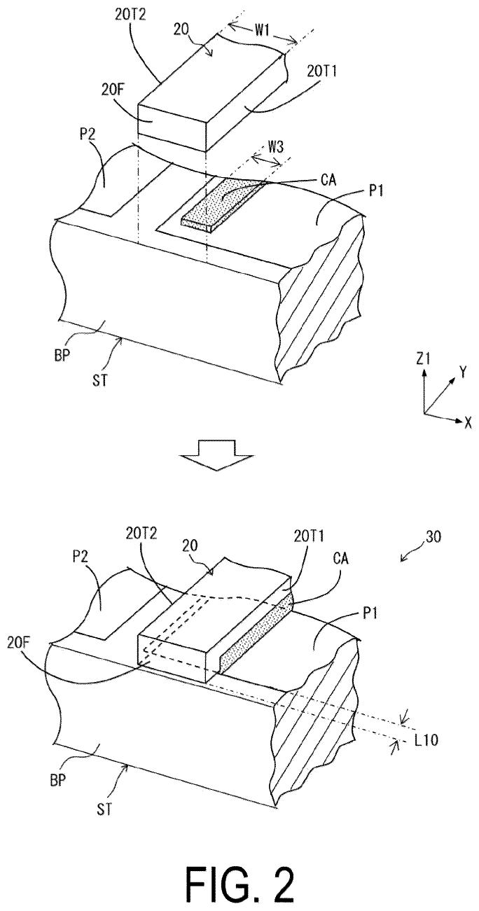

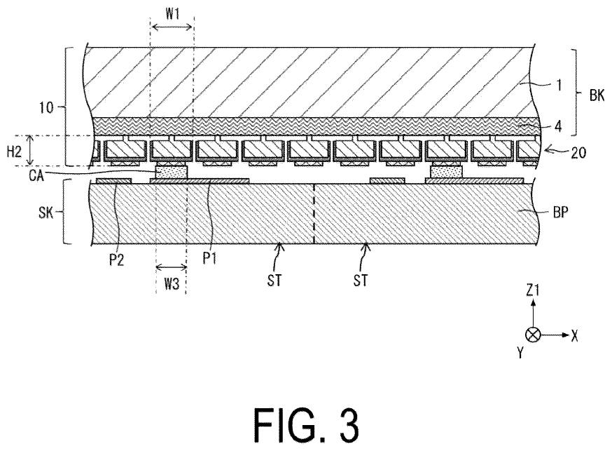

The light-emitting element 30 in the present embodiment will be further described below with reference to FIGS. 2 and 3. FIG. 2 is a perspective view schematically illustrating an example of a process of junction-down mounting a light emitter on a support body. FIG. 3 is a cross-sectional view illustrating an example of a method for manufacturing the light-emitting element in the present embodiment. In FIG. 2, for the sake of clarity of illustration, the structure of the light emitter 20 is simplified, and the bonding material CA is hatched.

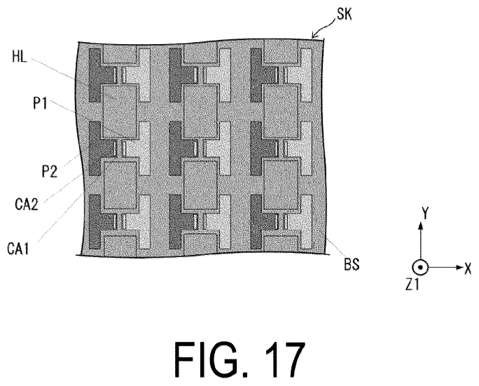

As illustrated in FIG. 2, the bonding material CA is disposed on the first pad P1 corresponding to a position mounted with the light emitter 20 on the support body ST. The support body ST may be a part of a support substrate SK (see FIG. 17 and the like) described later. The bonding material CA may include a conductive material having at least one selected from the group consisting of heating fluidity, pressure curability, a thermosetting property, and photocurability.

The bonding material CA disposed on the first pad P1 has a certain thickness (height in the Z1-axis direction) at a time point before the light emitter 20 is bonded. The thickness of the bonding material CA may be larger than the thickness of the second type semiconductor portion S2. For example, the thickness of the bonding material CA can be about 5 μm, and the thickness of the second type semiconductor portion S2 can be about 0.5 μm. In the bonding material CA, wettability with the first pad P1 is larger than wettability with the base portion BP. When the light emitter 20 is junction-down mounted on the support body ST, the bonding material CA wets and spreads on the first pad P1.

The width W1 of the light emitter 20 may be, for example, 120 μm or less, 100 μm or less, 80 μm or less, or 60 μm or less. The lower limit of the width W1 of the light emitter 20 is not particularly limited, but the width W1 may be, for example, 40 μm or more. A width W3 of the bonding material CA may be, for example, 10 μm or more from the viewpoint of reducing the possibility of bonding failure. The width W3 of the bonding material CA may be smaller than the width W1, may be equal to the width W1, or may be larger than the width W1.

At the time point before the light emitter 20 is bonded to the support body ST, the light emitter 20 may be held by, for example, a general holding means (collet or the like) or may be held by a growth substrate (see, for example, FIG. 3). Two side surfaces of the light emitter 20 facing each other in the X-axis direction are called side surfaces 20T1 and 20T2, and an end surface in the Y-axis direction of the light emitter 20 is called an end surface 20F. Hereinafter, the side surfaces 20T1 and 20T2 may be collectively called a side surface 20T.

In the light-emitting element 30, the bonding material CA can go up along the side surface 20T of the light emitter 20. In the example illustrated in FIG. 2, the bonding material CA can go up along the side surface 20T1, and the bonding material CA can go up along the side surface 20T2. In the light-emitting element 30 in the present embodiment, the second type semiconductor portion S2 exists between the bonding material CA having gone up and (the first side surface FS of) the first type semiconductor portion S1 (see FIG. 1). Therefore, it is possible to effectively reduce the possibility that the first electrode E1 and the first type semiconductor portion S1 are short-circuited via the bonding material CA.

When the light emitter 20 is, for example, a semiconductor laser diode, a resonator end surface is formed on the end surface 20F and is not covered with the second type semiconductor portion S2. The light emitter 20 may be junction-down mounted on the support body ST, and thus the end surface 20F of the light-emitting element 30 bulges (protrudes) with respect to the first pad P1 in the Y-axis direction. Since the first pad P1 is thin, illustration of the end surface of the first pad P1 is omitted in FIG. 2. The light-emitting element 30 may have a distance L10 in the Y-axis direction from the end surface of the first pad P1 to the end surface 20F of the light emitter 20, and in this case, the possibility that the bonding material CA goes up along the end surface 20F can be reduced.

In the light emitter 20, the side surface 20T2 closer to the second pad P2 (the negative side in the X-axis direction) of the two side surfaces 20T protrudes with respect to the first pad P1 in the X-axis direction. In this case, the possibility that the bonding material CA goes up along the side surface 20T2 can be reduced. On the other hand, the bonding material CA can go up along the side surface 20T1.

The bonding material CA may have fluidity, and may typically be solder. The bonding material CA may be, for example, a solder pump, or may be a solder thin film formed by printing, vapor deposition, or sputtering.

Use of the bonding material CA having fluidity has, for example, the following advantages. That is, as illustrated in FIG. 3, there is a case where two or more light emitters 20 are simultaneously transferred to one support substrate SK in one process by using the semiconductor substrate 10 including a plurality of the light emitters 20 and the support substrate SK. Although described in detail in examples described later, the semiconductor substrate 10 may include a main substrate 1, a foundation 4, and the plurality of light emitters 20. In the example illustrated in FIG. 3, at least a part of the first type semiconductor portion S1 included in the light emitter 20 may be formed by an epitaxial lateral overgrowth (ELO) method.

The distance from a boundary between the light emitter 20 and the foundation 4 to the surface on the support substrate SK side of the first electrode E1 is defined as a height H2 of each light emitter 20. The plurality of light emitters 20 can have slightly different heights H2. Since the bonding material CA has fluidity, even when there is a difference in the height H2, the two or more light emitters 20 can easily be transferred to the support substrate SK at a time separated from the base substrate BK. After the light emitters 20 are transferred to the support substrate SK, the base portion BP may be split. This can form the light-emitting element 30 in which at least one light emitter 20 is junction-down mounted on the support body ST.

When the bonding material CA has fluidity, the controllability of the existence range of the bonding material CA can decrease when the light emitter 20 and the support substrate SK are brought close to each other and applied with a load. When the width W1 of the light emitter 20 is small, the bonding material CA easily goes up on the side surface 20T of the light emitter 20. When the width W3 of the bonding material CA is narrowed, the transfer yield can decrease due to a decrease in bonding force and a demand for a high mounting accuracy (alignment).

In the light-emitting element 30 in the present embodiment, even when the bonding material CA goes up on the side surface 20T of the light emitter 20, the second type semiconductor portion S2 exists between the bonding material CA having gone up and (the first side surface FS of) the first type semiconductor portion S1 (see FIG. 1). Therefore, it is possible to effectively reduce the possibility that the first electrode E1 and the first type semiconductor portion S1 are short-circuited via the bonding material CA while securing the size of the width W3 of the bonding material CA.

Since the bonding material CA goes up on the side surface 20T of the light emitter 20 (wraps around the side surface 20T), the light-emitting element 30 in the present embodiment has the following advantages. That is, the bonding force between the support substrate SK and the light emitter 20 via the bonding material CA can be improved, and the light emitter 20 can be suppressed by the bonding material CA. When the bonding material CA comes into contact with a part of the side surface 20T to at least partially hold the light emitter 20, the bonding strength between the support substrate SK and the light emitter 20 is improved. Accordingly, when the light emitter 20 is separated from the base substrate BK, the bonding material CA and the light emitter 20 are hardly separated from each other, and thus the light emitter 20 is easily separated from the base substrate BK. The heat dissipation of the light emitter 20 can be easily improved. When the go-up height H1 of the bonding material CA exceeds the lower surface level LV of the first type semiconductor portion S1, the above effect becomes more remarkable.

### Method for Manufacturing Light-Emitting Element

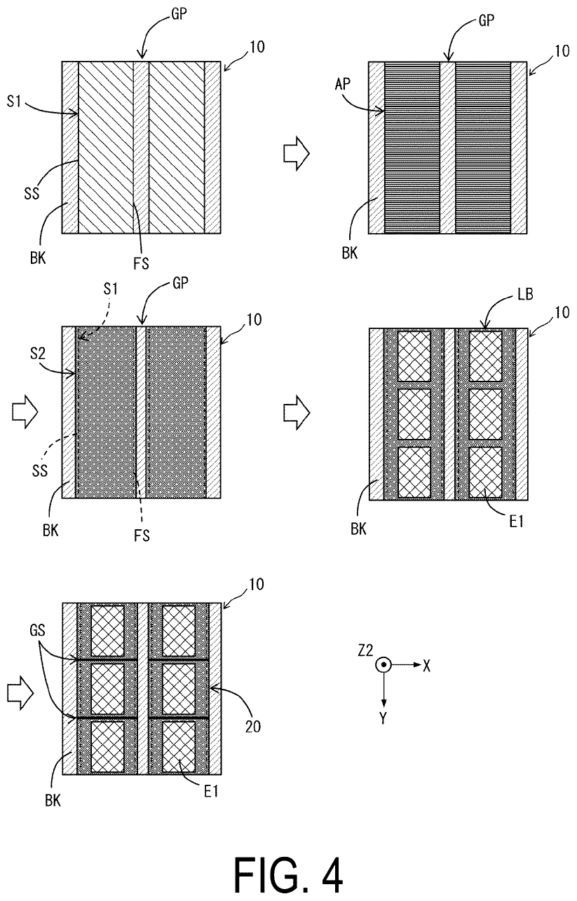

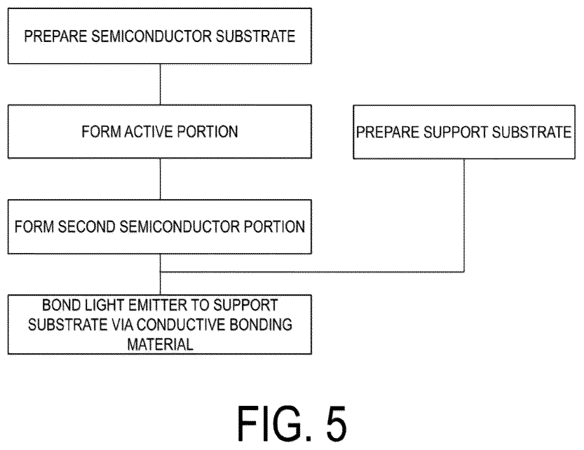

FIG. 4 is a plan view schematically illustrating an example of the method for manufacturing a light-emitting element in the present embodiment. FIG. 5 is a flowchart showing an example of the method for manufacturing the light-emitting element in the present embodiment. In the example illustrated in FIG. 4, the light emitter 20 may be a laser body having a double-sided electrode structure. Other methods for manufacturing various light emitters 20 will be described later as examples. In FIG. 4, for the sake of clarity of illustration, each member in the plan view is hatched identically to each member in the cross-sectional view illustrated in FIG. 1 and the like.

As illustrated in FIGS. 4 and 5, the method for manufacturing the light-emitting element 30 in the present embodiment includes: preparing the semiconductor substrate 10 in which the first type semiconductor portion S1 having the first side surface FS is formed on the base substrate BK; forming the active portion AP above the first type semiconductor portion S1; and forming the second type semiconductor portion S2 reaching laterally the first type semiconductor portion S1 from above the active portion AP.

In FIG. 4, a layer such as the first type semiconductor portion S1 is layered on the base substrate BK, and this layering direction is defined as an upward direction (positive side in the Z2-axis direction). The orientation of the Z2-axis may be reversed with respect to the Z1-axis described in FIG. 1 and the like. For example, in the case of performing the junction-down mounting as illustrated in FIG. 3, the semiconductor substrate 10 is inverted up and down with respect to the support substrate SK. Correspondingly, in the following description in the present description, the X-Y-Z1-axis and the X-Y-Z2-axis may be selectively used depending on the target of the description. The positive and negative orientations in each of the X-Y-Z axes do not necessarily have an essential meaning, but for convenience of description, in the present description, the semiconductor substrate 10 is inverted with the X-axis as a rotation axis and junction-down mounted on the support substrate SK, and the X-axis and the Y-axis are used in common.

The semiconductor substrate 10 may have a plurality of first type semiconductor portions S1 having a bar shape arranged side by side in the X-axis direction. The first type semiconductor portion S1 may have a long shape with the Y-axis direction as a long direction. The first type semiconductor portion S1 may include a lateral growth portion formed by the ELO method and a longitudinal growth portion (regrowth portion) formed above the lateral growth portion by general epitaxial growth.

The semiconductor substrate 10 may have a gap GP between the adjacent first type semiconductor portions S1. By setting the condition that the second type semiconductor portion S2 is formed to enter the gap GP, the second type semiconductor portion S2 can be formed to cover at least a part of the first side surface FS.

The gap GP may be a space formed by stopping lateral growth before adjacent crystalline bodies grown by the ELO method associate with each other when at least a part of the first type semiconductor portion S1 is formed by the ELO method. Alternatively, the gap GP may be a trench formed by etching the first type semiconductor portion S1 formed in a plate shape. The base substrate BK may be a growth substrate used for forming the first type semiconductor portion S1. In the base substrate BK, the light emitters 20 may be separable when the light emitter 20 is transferred to the support substrate SK. For example, the base substrate BK may include an S1 substrate or an SiC substrate and a seed layer (e.g., a GaN-based semiconductor), or the base substrate BK may be a GaN-based self-standing substrate (single crystal substrate).

The first type semiconductor portion S1 may have the first side surface FS, which is one of the two side surfaces facing each other in the X-axis direction, and a second side surface SS, which is the other. The first side surface FS and the second side surface SS are side surfaces at the time of forming the first type semiconductor portion S1, and may include a crystal plane of a nitride semiconductor. In the present description, a plane spontaneously generated by crystal growth may be called a “crystal plane”, and a plane formed by processing such as etching may be called a “processed plane”. A plane formed by cleavage of a crystal is called a “cleavage plane”.

The second type semiconductor portion S2 may reach laterally a side of the first side surface FS in the first type semiconductor portion S1 from above the active portion AP, and may reach laterally the side of the second side surface SS in the first type semiconductor portion S1 from above the active portion AP.

When the light emitter 20 is a laser body, a ridge (not illustrated) may be formed in the second type semiconductor portion S2, and the first electrode E1 may overlap the ridge in plan view. In the present description, “two members overlap” means that at least a part of one member overlaps the other member in plan view (including perspective plan view) viewed in the thickness direction of each member, and these members may be in contact with each other or need not be in contact with each other.

The first electrode E1 may include a contact electrode and an auxiliary electrode (sometimes called a pad electrode). A plurality of the first electrodes E1 arranged in the Y-axis direction may be formed above the second type semiconductor portion S2. A plurality of open grooves GS is formed in a layered body LB having a long shape including the first type semiconductor portion S1, the active portion AP, the second type semiconductor portion S2, and the first electrode E1. Thus, the layered body LB is split into the plurality of light emitters 20. The open groove GS may be a gap space formed by cleavage of the layered body LB, or may be a gap space formed by etching the layered body LB.

The method for manufacturing the light-emitting element 30 in the present embodiment further includes: preparing the support substrate SK; and bonding the light emitter 20 including at least a part of each of the first type semiconductor portion S1, the active portion AP, and the second type semiconductor portion S2 to the support substrate SK via the bonding material (conductive bonding material) CA, and thus the first type semiconductor portion S1 is positioned higher than the active portion AP. These processes can be understood with reference to the above description, FIG. 3, and the like, and thus repeated description will be omitted. When the light emitter 20 has a double-sided electrode structure, after the light emitter 20 is transferred to the support substrate SK, the second electrode E2 electrically connected to the first type semiconductor portion S1 can be formed on the surface of the light emitter 20 on the side opposite to the side provided with the first electrode E1. Thereafter, the second electrode E2 and the second pad P2 can be electrically connected using a conductive film or the like.

### Device for Manufacturing

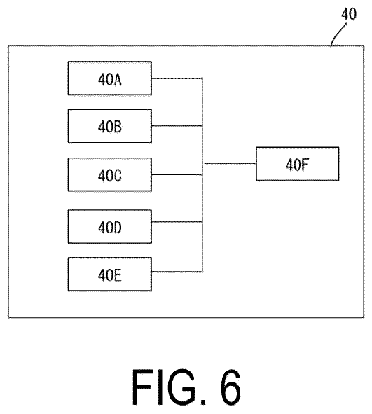

FIG. 6 is a block diagram illustrating an example of a device for manufacturing a light-emitting element in the present embodiment. A device 40 for manufacturing in FIG. 6 may include a device 40A that prepares the semiconductor substrate 10, a device 40B that forms the active portion AP, a device 40C that forms the second type semiconductor portion S2, a device 40D that prepares the support substrate SK, a device 40E that bonds the light emitter 20 to the support substrate SK, and a device 40F that controls the devices 40A to 40E. The device 40 for manufacturing may appropriately include a device for executing various specific processes described in examples described later.

As the device 40B and the device 40C, for example, a metal-organic chemical vapor deposition (MOCVD) device can be used. As the device 40 for manufacturing, a sputtering device or a photolithography device may be appropriately used.

The device 40F may include a processor and a memory. The device 40F may control the devices 40A to 40E by executing a program stored, for example, in a built-in memory, a communicable communication device, or an accessible network.

When the semiconductor substrate 10 prepared in advance is used, the device 40 for manufacturing need not include the device 40A. When the support substrate SK prepared in advance is used, the device 40 for manufacturing need not include the device 40D.

### Another Configuration Examples

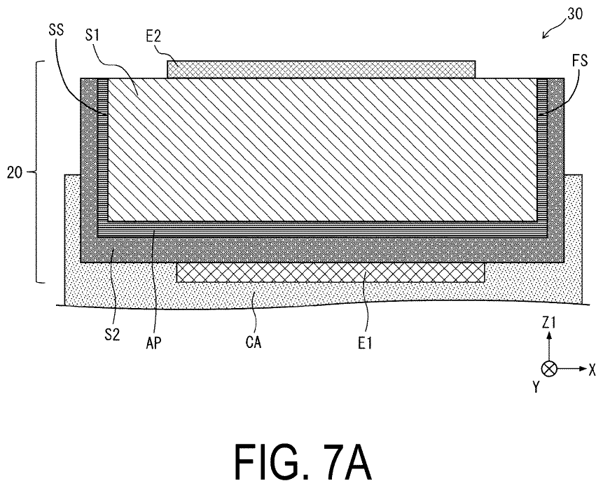

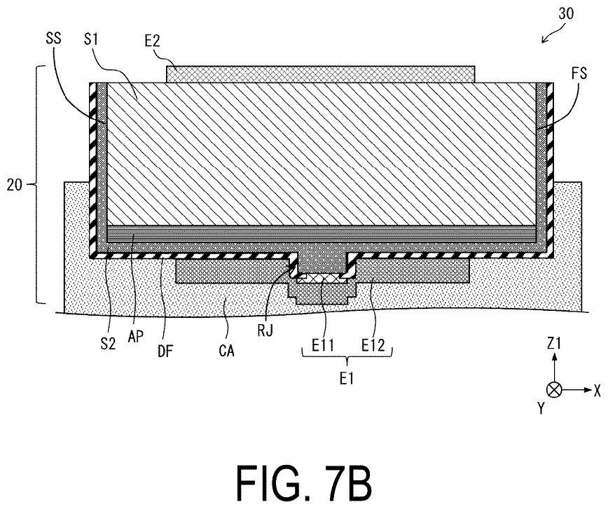

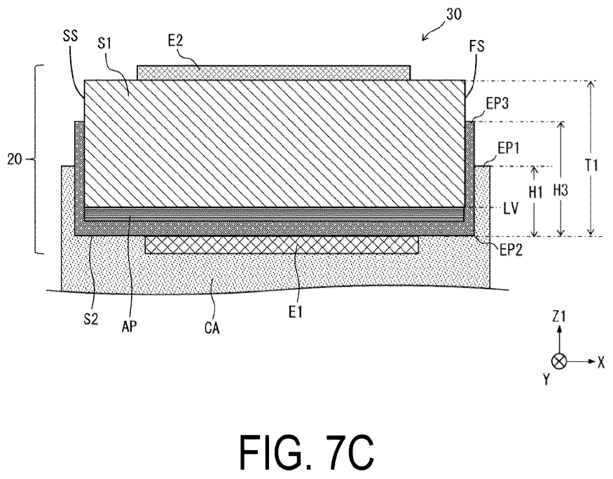

FIG. 7A is a cross-sectional view illustrating a light-emitting element in another configuration example of the embodiment of the present disclosure. As illustrated in FIG. 7A, in the light-emitting element 30, the active portion AP may reach laterally the first type semiconductor portion S1 from below the first type semiconductor portion S1. In the light-emitting element 30, the active portion AP may reach, from below the first type semiconductor portion S1, laterally the first side surface FS in the first type semiconductor portion S1 and reach laterally the side of the second side surface SS. Since the film thickness of the active portion AP is very thin, the thickness of the active portion AP is exaggerated in FIG. 7A.

FIG. 7B is a cross-sectional view illustrating the light-emitting element 30 in another configuration example of the embodiment of the present disclosure. In the light emitter 20, a ridge RJ may be formed in the second type semiconductor portion S2. The ridge RJ may be at a position overlapping the first electrode E1 in plan view, and the first electrode E1 may include a first contact electrode E11 and a first auxiliary electrode E12. The light-emitting element 30 may be provided an insulating film DF on both sides of the ridge RJ, and the insulating film DF may reach laterally the first type semiconductor portion S1 from below the second type semiconductor portion S2 excluding the ridge RJ. In the light-emitting element 30, the insulating film DF may reach, from below the second type semiconductor portion S2 excluding the ridge RJ, laterally the first side surface FS in the first type semiconductor portion S1 and reach laterally the side of the second side surface SS. The insulating film DF positioned on both sides of the ridge RJ and the insulating film DF positioned laterally in the first type semiconductor portion S1 may be formed integrally (continuously) with each other, or may be formed separately. For example, after the insulating film DF (first insulating film) is formed on both sides of the ridge RJ and a lower surface of the second type semiconductor portion S2, the insulating film DF (second insulating film) positioned laterally on the first type semiconductor portion S1 may be formed.

In the light-emitting element 30, the second type semiconductor portion S2 may exist between the first side surface FS and the insulating film DF, and the second type semiconductor portion S2 need not exist. In the light-emitting element 30 of the example illustrated in FIG. 7B, even when the second type semiconductor portion S2 does not exist laterally on the first side surface FS, the insulating film DF exists between the first side surface FS and the bonding material CA. Due to this, it is possible to effectively reduce the possibility that the first electrode E1 and the first type semiconductor portion S1 are short-circuited via the bonding material CA. The light-emitting element 30 may have a configuration in which the light emitter 20 is, for example, a light-emitting diode and does not include the ridge RJ in the example illustrated in FIG. 7B.

FIG. 7C is a cross-sectional view illustrating the light-emitting element 30 in another configuration example of the embodiment of the present disclosure. The second type semiconductor portion S2 may reach laterally the first type semiconductor portion S1 from below the active portion AP, may be over the entire surface of the first side surface FS laterally in the first type semiconductor portion S1 (see FIG. 1), or may cover a part of the first side surface FS. That is, the first side surface FS may have a lateral part where the second type semiconductor portion S2 is not positioned, and for example, a part of the first side surface FS may be exposed. In the cross section orthogonal to the Y-axis direction as illustrated in FIG. 7C, the height in the Z1-axis direction of the second type semiconductor portion S2 positioned laterally in the first type semiconductor portion S1 is called a formation height H3. An end in the Z1-axis direction above the second type semiconductor portion S2 positioned laterally in the first type semiconductor portion S1 is called EP3, and the formation height H3 is a height position of the end EP3 higher than the end EP2 with reference to the position of the end EP2 on the lower side of the second type semiconductor portion S2 in the Z1-axis direction.

In the present embodiment, the second type semiconductor portion S2 reaches laterally the first type semiconductor portion S1 from below the active portion AP. That is, the second type semiconductor portion S2 is positioned below the active portion AP and literally on at least a part of the first side surface FS. The second type semiconductor portion S2 may be continuous from below the active portion AP to the end EP3.

In the light-emitting element 30, the size of the formation height H3 may be smaller than a sum T1 of the thicknesses of the first type semiconductor portion S1, the active portion AP, and the second type semiconductor portion S2 in the Z1-axis direction. In the light-emitting element 30, the reaching position of a wraparound part of the second type semiconductor portion S2 (the position of the end EP3) is above a go-up position of the bonding material CA (the position of the end EP1). For example, in the light-emitting element 30, in the cross section orthogonal to the Y-axis direction as illustrated in FIG. 7C, the position of the end EP3 may be above the center of the first side surface FS, or may be above ¼ height of the first side surface FS. In the light-emitting element 30, since the formation height H3 of the second type semiconductor portion S2 is larger than the go-up height H1 of the bonding material CA, it is possible to effectively reduce the possibility that the first electrode E1 and the first type semiconductor portion S1 are short-circuited via the bonding material CA. In the example illustrated in FIG. 7C, the lateral of the first side surface FS of the light-emitting element 30 may be covered with the insulating film DF (see FIG. 7B). The light-emitting element 30 may have the configuration on the side of the second side surface SS (arrangement relationship of each portion) that is the same as that described above for the first side surface FS.

### Example 1

Hereinafter, one example of the present disclosure will be described in detail. Hereinafter, each configuration of a plurality of examples of the present disclosure will be described with the same or corresponding parts in the drawings being denoted by the same reference signs, but unless otherwise specified, forms obtained by appropriately combining technical means disclosed in the above-described embodiment and different examples described later are also included in the technical scope of the present disclosure.

In Example 1, an example will be described in which the light emitter 20 is a laser body (semiconductor laser chip) having a single-sided two-electrode structure, and the light-emitting element 30 is a laser element. Hereinafter, for the sake of clarity of description, the configuration of the light emitter 20 will be first described, and then the light-emitting element 30 will be described together with the description of the method for manufacturing the light-emitting element.

### Light Emitter

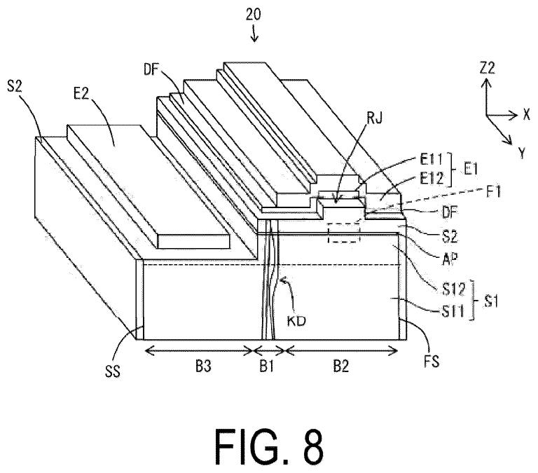

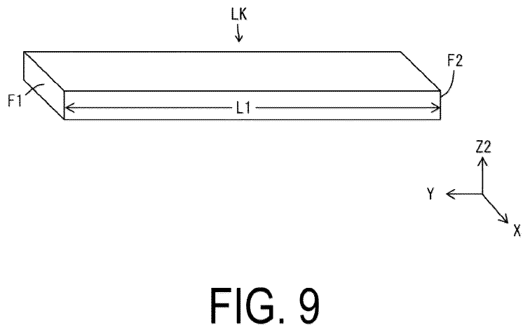

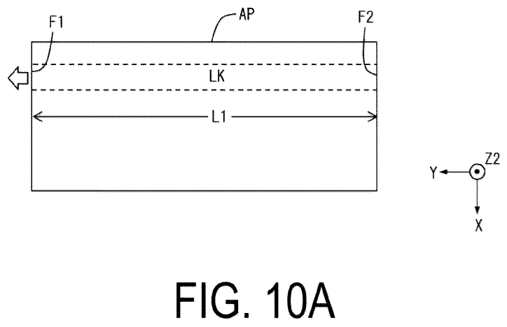

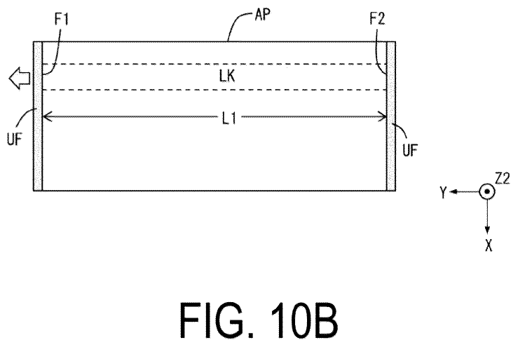

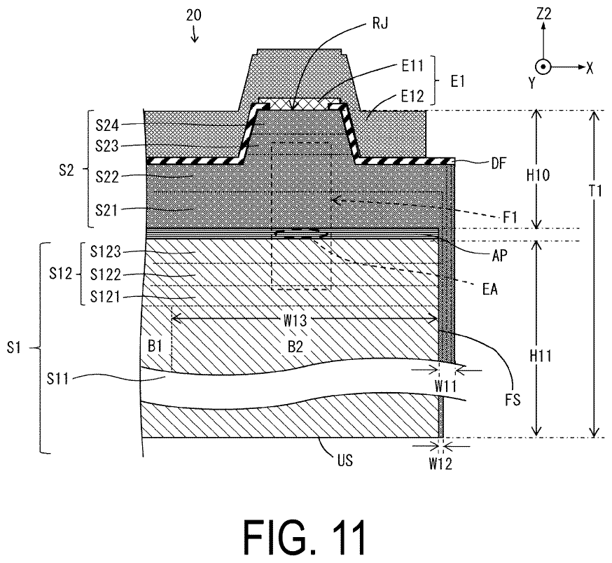

FIG. 8 is a perspective view illustrating the configuration of a light emitter in Example 1. FIG. 9 is a perspective view illustrating the configuration of an optical resonator. FIGS. 10A and 10 are plan views illustrating the configuration of the active portion. FIG. 11 is a cross-sectional view illustrating the configuration of the light emitter in Example 1.

As illustrated in FIGS. 8 to 11, the light emitter 20 in Example 1 may include the first type semiconductor portion S1, the active portion AP positioned above the first type semiconductor portion S1, and the second type semiconductor portion S2 reach laterally the first type semiconductor portion S1 from above the active portion AP. The second type semiconductor portion S2 may cover at least a part of the first side surface FS of the first type semiconductor portion S1.

Each of the first type semiconductor portion S1, the active portion AP, and the second type semiconductor portion S2 may include a nitride semiconductor (e.g., a GaN-based semiconductor). In FIG. 8 and the like, the X direction is the <11-20> direction (a-axis direction) of the nitride semiconductor crystal (wurtzite structure), the Y direction is the <1-100> direction (m-axis direction) of the nitride semiconductor crystal, and the Z2 direction is the <0001> direction (c-axis direction) of the nitride semiconductor crystal. The first side surface FS, which is one of the two side surfaces facing each other in the a-axis direction of the first type semiconductor portion S1, and the second side surface SS, which is the other, are included. The second type semiconductor portion S2 reaches laterally the first side surface FS in the first type semiconductor portion S1 from above the active portion AP and reaches laterally the side of the second side surface SS.

The light emitter 20 is a laser body having a ridge structure (ridge waveguide structure), and the second type semiconductor portion S2 includes the ridge RJ. The light emitter 20 includes at least a part of each of the first type semiconductor portion S1, the active portion AP, and the second type semiconductor portion S2, and includes an optical resonator LK including a pair of resonator end surfaces F1 and F2. The first side surface FS of the first type semiconductor portion S1 is closer to the ridge RJ than the second side surface of the first type semiconductor portion S1 positioned opposite to the first side surface FS.

The light emitter 20 may include the first electrode E1, which is an anode, and the second electrode E2, which is a cathode. The first electrode E1 may include the first contact electrode E11 and the first auxiliary electrode E12. Although not illustrated, the second electrode E2 may include a second contact electrode and a second auxiliary electrode.

The first type semiconductor portion S1 may include a base semiconductor portion S11 and a first mold portion S12. The base semiconductor portion S11 may include a part formed using the ELO method. The first mold portion S12 may be a crystal portion having the first type conductivity further formed above the base semiconductor portion S11 by, for example, the MOCVD method after the base semiconductor portion S11 is formed by the ELO method. The base semiconductor portion S11 and the first mold portion S12 may have conductivity of the same type. In Example 1, the first type semiconductor portion S1 includes an n-type semiconductor portion having a donor, and the second type semiconductor portion S2 includes a p-type semiconductor portion having an acceptor.

The first type semiconductor portion S1 includes a first portion (center portion) B1, and a second portion (wing portion) B2 and a third portion B3 in which the density (threading dislocation density) of threading dislocation KD extending in the thickness direction (Z2 direction) is smaller than that of the first portion B1. The second portion (wing) B2 is closer to the first side surface FS than the first portion (center portion) B1 in the a-axis direction. The third portion B3, the first portion B1, and the second portion B2 are arranged in this order in the X direction, and the first portion B1 is positioned between the third portion B3 and the second portion B2. The first portion B1 is a part positioned on an opening of a mask when the base semiconductor portion S11 is formed by the ELO method (described later). The threading dislocation densities of the second portion B2 and the third portion B3 may be ⅕ or less (e.g., 5×10⁶/cm² or less) of the threading dislocation density of the first portion B1. The threading dislocation can be observed by performing, for example, cathode luminescence (CL) measurement on the surfaces of the first type semiconductor portion S1 and the second type semiconductor portion S2 or cross sections parallel to the surfaces.

The first mold portion S12 in the first type semiconductor portion S1 may include a first contact S121, a first cladding portion S122, and a first light guide S123 formed in this order upward from the base semiconductor portion S11. The second type semiconductor portion S2 may include a second light guide S21, an electron blocking portion S22, a second light cladding portion S23, and a second contact S24 formed in this order upward from the active portion AP. The first contact electrode E11 may be formed on the second contact S24. Each portion included in the first mold portion S12, the active portion AP, and each portion included in the second type semiconductor portion S2 may each have a layer shape (e.g., the active portion AP may be an active layer).

In Example 1, the second electrode E2 is provided on the same side as the first electrode E1 with respect to the first type semiconductor portion S1. The second electrode E2 is in contact with the first type semiconductor portion S1, and the first and second electrodes E1 and E2 do not overlap in plan view. Specifically, the first type semiconductor portion S1 may be larger in width in the X direction than the active portion AP and the second type semiconductor portion S2, and the second electrode E2 may be formed at an exposure part of the first type semiconductor portion S1. Parts of the first type semiconductor portion S1, the active portion AP, and the second type semiconductor portion S2 may be engraved by etching or the like to expose the base semiconductor portion S11. The first contact S121 of the first mold portion S12 may be exposed, and in this case, the second electrode E2 may be provided in contact with the first contact S121.

The first electrode E1 has a shape in which a direction (Y direction) of a resonator length L1 of the optical resonator LK is a long direction. The length in the Y direction of the first electrode E1 may be smaller than the resonator length L1, and in this case, the first electrode E1 does not hinder formation and split of the open groove GS in the layered body LB (see FIG. 4). The same may apply to the second electrode E2, and the length in the Y direction of the second electrode E2 may be smaller than the resonator length L1.

For example, the optical resonator LK may include a part overlapping the first contact electrode E11 in plan view in each of the first mold portion S12, the active portion AP, the second light guide S21, the electron blocking portion S22, and the second light cladding portion S23.

The resonator length L1, which is the distance between the pair of resonator end surfaces F1 and F2, may be 200 [μm] or less, may be 150 [μm] or less, or may be 100 [μm] or less. The lower limit of the resonator length L1 is not particularly limited as long as the optical resonator LK can function, and may be 50 [μm], for example.

At least one of the pair of resonator end surfaces F1 and F2 may be included in the end surface 20F of the light emitter 20 formed by cleaving the layered body LB (see FIG. 4). Each of the pair of resonator end surfaces F1 and F2 may include an m-plane of a nitride semiconductor crystal (e.g., a GaN-based semiconductor crystal).

After the light emitter 20 is transferred to the support substrate SK (see FIG. 3), a reflecting mirror film UF (e.g., a dielectric film) covering each of the resonator end surfaces F1 and F2 may be formed. The light reflectance of the resonator end surface F2 on the light reflecting surface side is larger than the light reflectance of the resonator end surface F1. Although not illustrated in FIG. 8, the reflecting mirror film UF can be formed on the entire cleavage planes (m-planes) of the first type semiconductor portion S1 and the second type semiconductor portion S2.

In the optical resonator LK, the refractive index (optical refractive index) decreases in the order of the active portion AP, the first light guide S123, and the first cladding portion S122, and the refractive index decreases in the order of the active portion AP, the second light guide S21, and the second light cladding portion S23. Therefore, light generated by coupling, in the active portion AP, a hole supplied from the first electrode E1 and an electron supplied from the second electrode E2 is confined in the optical resonator LK (in particular, the active portion AP), and laser oscillation occurs due to the stimulated emission and feedback action in the active portion AP. The laser light generated by the laser oscillation is emitted from a light emission region EA of the resonator end surface F1 on an emission surface side.

The second type semiconductor portion S2 may include the ridge RJ overlapping the first contact electrode E11 in plan view, and the ridge RJ may include the second light cladding portion S23 and the second contact S24. The ridge RJ has a shape in which the Y direction is the long direction, and is provided with the insulating film DF to cover a side surface of the ridge RJ. Both ends in the X direction of the first contact electrode E11 may overlap the insulating film DF in plan view. The first auxiliary electrode E12 may overlap the first electrode E1 and the insulating film DF in plan view. The refractive index of the insulating film DF is smaller than the refractive indices of the second light guide S21 and the second light cladding portion S23. By providing the ridge RJ and the insulating film DF, the current path between the first electrode E1 and the first type semiconductor portion S1 is narrowed on the anode side, and light can be efficiently emitted in the resonator LK.

The ridge RJ overlaps the second portion B2 (low dislocation portion) of the first type semiconductor portion S1 in plan view, and does not overlap the first portion B1. In this way, the current path from the first electrode E1 to the second electrode E2 via the second type semiconductor portion S2 and the first type semiconductor portion S1 is formed in a part overlapping the second portion B2 in plan view (part having few threading dislocation), and the light emission efficiency in the active portion AP is enhanced. This is because the threading dislocation acts as a non-light-emission recombination center.

Since the light emitter 20 in Example 1 has the single-sided two-electrode structure, the size of the bonding portion with respect to the width of the bonding material CA becomes relatively small when the light emitter 20 is junction-down mounted on, for example, the support substrate SK (see FIG. 3). Therefore, in plan view, the edge ED1 of the bonding material CA easily protrudes from the light emitter 20. As a result, the bonding material CA can easily go up on the first side surface FS.

When the raw material for forming the film of the second type semiconductor portion S2 enters the gap GP formed between the plurality of first type semiconductor portions S1, the second type semiconductor portion S2 laterally on the first side surface FS can be formed. By changing film formation conditions, the size of the gap GP, and the like, the second type semiconductor portion S2 can be easily formed laterally on the first side surface FS. The second type semiconductor portion S2 laterally on the first side surface FS may be formed simultaneously when each portion included in the second type semiconductor portion S2 is formed on the active portion AP, and may be a multilayer film including layers corresponding to the second light guide S21, the electron blocking portion S22, and the like.

In the cross section illustrated in FIG. 11, the height of the second type semiconductor portion S2 in the Z2 direction is called H10. The height H10 may be a distance from the uppermost portion to the lowermost portion of the second type semiconductor portion S2 in the Z2 direction, in other words, a distance from a boundary between the second contact S24 and the first contact electrode E11 to a boundary between the second light guide S21 and the active portion AP. The height of the first type semiconductor portion S1 in the Z2 direction is called H11. A surface on the lower side in the Z2 direction of the first type semiconductor portion S1, in other words, a surface (back surface) on a side far from the active portion AP is called a lower surface US. The height H11 may be a distance from the uppermost portion to the lowermost portion of the first type semiconductor portion S1 in the Z2 direction, in other words, a distance from a boundary between the first light guide S123 and the active portion AP to the lower surface US. When the surface of the lower surface US has some undulations, the position of a virtual plane in which the surface of the lower surface US is virtually smoothed can be the position of the lower surface US in the Z2 direction.

The thickness in the X direction of the second type semiconductor portion S2 positioned laterally on the first side surface FS of the first mold portion S12 is called a width W11, and the thickness in the X direction of the second type semiconductor portion S2 positioned laterally on the first side surface FS in the vicinity of the lower surface US of the base semiconductor portion S11 is called a width W12. The width W12 may be smaller than the width W11. This is because the closer to the lower surface US, the more difficult the material for formation of the second type semiconductor portion S2 is supplied. The “vicinity of the lower surface US” mentioned here may be a part where the height from the lower surface US is 1/10 or less of the height H11.

The thickness (height H10) of the second type semiconductor portion S2 may be smaller than the thickness (height H11) of the first type semiconductor portion S1. The thickness of the active portion AP is so very thin that the active portion AP need not be formed to wrap around the first side surface FS. In this case, the second type semiconductor portion S2 may be in contact with the first side surface FS. Unlike the example illustrated in FIG. 11, the active portion AP may be formed to wrap around the first side surface FS.

The height H10 may be 75% or less, or 50% or less of the height H11. The sum T1 of the thicknesses of the first type semiconductor portion S1, the active portion AP, and the second type semiconductor portion S2 can be 50 [μm] or less. When the sum T1 of the thicknesses is too large, cleavage to a resonator length of 200 μm or less can be difficult.

The ratio of the resonator length L1 to the thickness (the height H11) of the second portion B2 of the first type semiconductor portion S1 can be 1 to 100. The direction orthogonal to the direction of the resonator length L1 can be the first direction (X direction), the size in the X direction of the second portion B2 can be a width W13 of the second portion B2, and the ratio of the resonator length L1 to the width W13 of the second portion B2 can be 1 to 100.

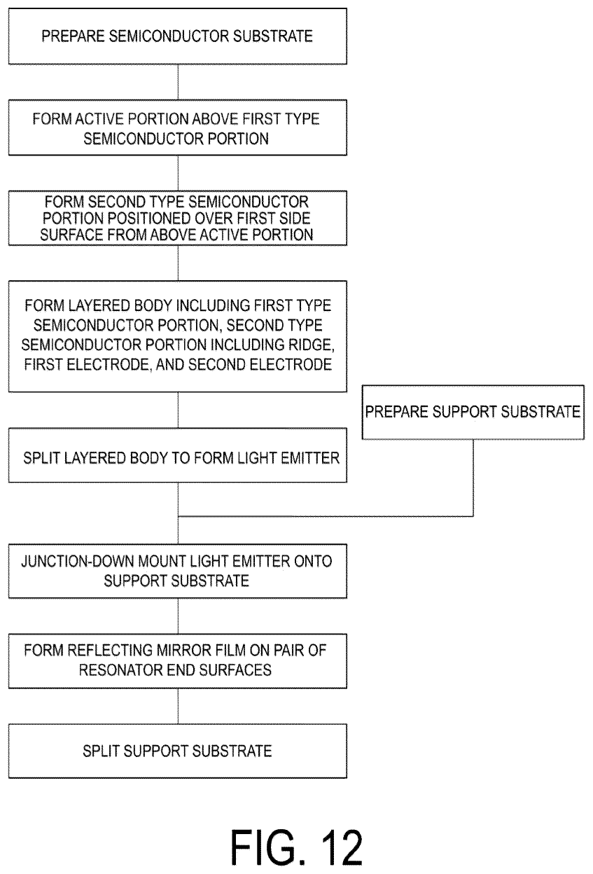

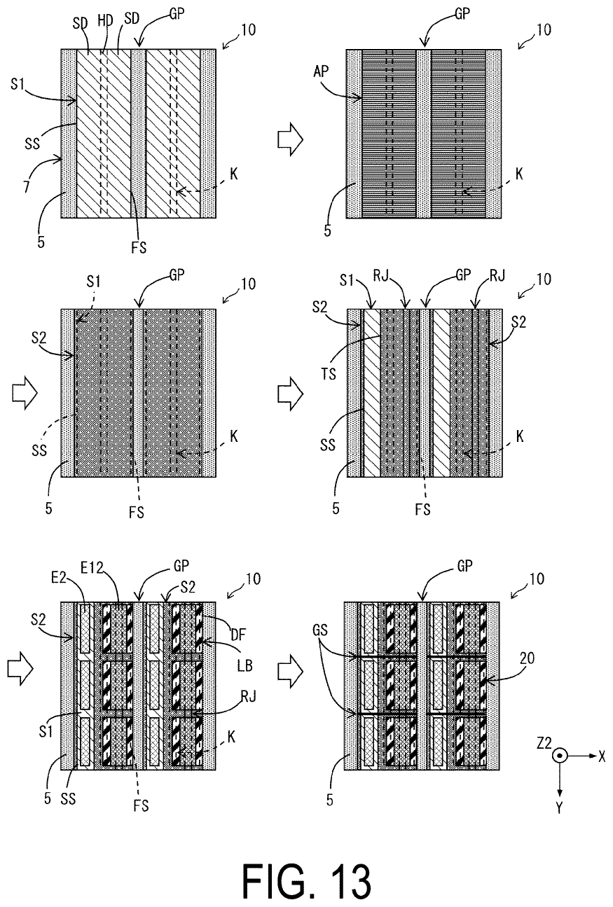

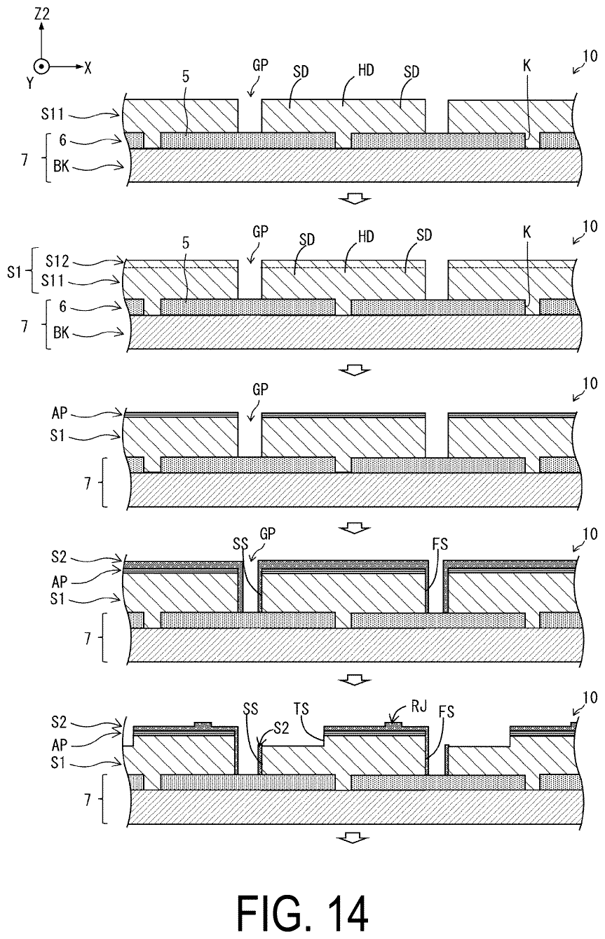

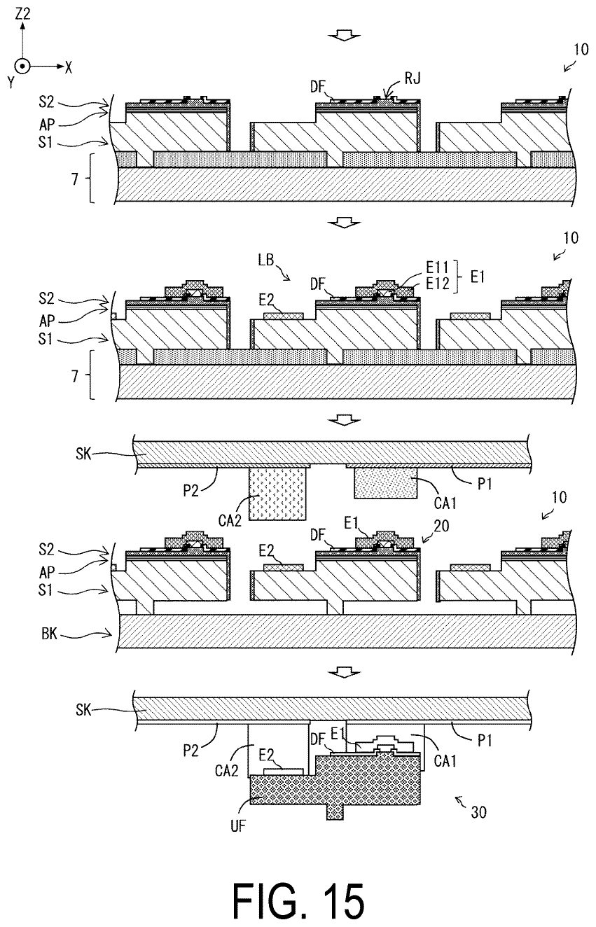

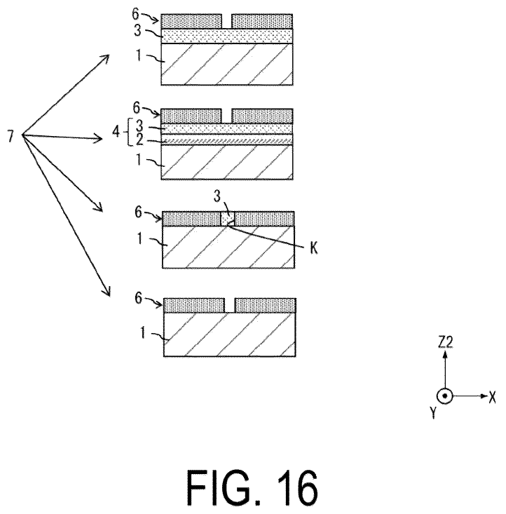

Method for Manufacturing Light-Emitting Element FIG. 12 is a flowchart schematically showing a method for manufacturing a light-emitting element in Example 1. FIG. 13 is a plan view schematically illustrating a method for manufacturing a light emitter included in the light-emitting element in Example 1. FIGS. 14 and 15 are cross-sectional views schematically illustrating the method for manufacturing the light-emitting element in Example 1. FIG. 16 is a cross-sectional view illustrating a configuration example of a template substrate. In FIG. 15, the lowermost view among the plurality of views illustrated along the flow of processing from the top to the bottom is a side view illustrating the end surface of the light-emitting element 30 for convenience of description.

In the method for manufacturing the light-emitting element of Example 1, first, the semiconductor substrate 10 is prepared as illustrated in FIGS. 12 to 15. The semiconductor substrate 10 includes a template substrate 7 and a plurality of base semiconductor portions S11 having a bar shape arranged side by side in the X direction above the template substrate 7. The template substrate 7 includes, for example, the base substrate BK and a mask 6 having a stripe shape. The mask 6 is formed above the base substrate BK and includes an opening K and a mask portion 5. The semiconductor substrate 10 including the first type semiconductor portion S1 may be prepared by forming the first mold portion S12 above the base semiconductor portion S11 with respect to such the semiconductor substrate 10. The semiconductor substrate 10 including the first type semiconductor portion S1 may be prepared by continuously forming the base semiconductor portion S11 and the first mold portion S12 above the template substrate 7.

Hereinafter, an example in which the semiconductor substrate 10 is prepared by forming the base semiconductor portion S11 using the ELO method on the template substrate 7 and further forming the first mold portion S12 will be described, but the present invention is not limited to this. The semiconductor substrate 10 can be prepared by performing various types of processing on the base substrate BK. A specific method for preparing the semiconductor substrate 10 is not particularly limited, and it is also within the scope of the present disclosure to prepare the semiconductor substrate 10 of Example 1 by processing a semi-finished product of the semiconductor substrate 10 in the middle stage of forming the semiconductor substrate 10. This will not be described repeatedly, and the same applies to the following examples.

### Template Substrate

The template substrate 7 includes the base substrate BK and the mask 6 positioned above the base substrate BK. As illustrated in FIG. 16, the template substrate 7 may have a configuration in which a seed 3 and the mask 6 are formed in this order on the main substrate 1, or a configuration in which the foundation 4 of a plurality of layers (including a buffer 2 and the seed 3) and the mask 6 are formed in this order on the main substrate 1. The seed 3 may be locally (e.g., in a stripe shape) formed to overlap the opening K of the mask 6 in plan view. The seed 3 may include a nitride semiconductor formed at a low temperature of 600° C. or lower. This can reduce warpage of the semiconductor substrate 10 (the template substrate 7 and the first type semiconductor portion S1) caused by stress of the seed 3. The seed 3 can also be formed using a sputtering device (pulse sputter deposition: PSD, pulse laser deposition: PLD, or the like). Use of the sputtering device has advantages that low-temperature film formation and large-area film formation are possible, cost reduction can be achieved, and the like. As illustrated in FIG. 16, the template substrate 7 may have a configuration in which the mask 6 is formed on the main substrate 1 (e.g., an SiC bulk crystal substrate or a GaN bulk crystal substrate).

As described above, the base substrate BK may include at least the main substrate 1. The base substrate BK may include the main substrate 1 and the seed 3 positioned above the main substrate 1, and may include the main substrate 1 and the foundation 4 positioned above the main substrate 1. A dissimilar substrate having a different lattice constant from that of the GaN-based semiconductor may be used for the main substrate 1. Examples of the dissimilar substrate include a single crystal silicon (Si) substrate, a sapphire (Al₂O₃) substrate, and a silicon carbide (SiC) substrate. The plane direction of the main substrate 1 is, for example, the (111) plane of the silicon substrate, the (0001) plane of the sapphire substrate, or the 6H—SiC (0001) plane of the SiC substrate. These are examples, and the main substrate 1 may be any material and plane direction that can grow the first type semiconductor portion S1 by the ELO method. A SiC (bulk crystal) substrate, a GaN (bulk crystal) substrate, or an AlN (bulk crystal) substrate can be used as the main substrate 1.

As the foundation 4 in FIG. 16, the buffer 2 and the seed 3 can be provided in order from the main substrate 1 side. For example, when a silicon substrate is used for the main substrate 1 and a GaN-based semiconductor is used for the seed 3, these (the main substrate and the seed) melt together, and thus the melting is reduced by providing the buffer 2 including an AlN layer and/or a silicon carbide (SiC) layer. The buffer 2 may have the effect of enhancing the crystallinity of the seed 3 and/or the effect of relaxing the internal stress of the first type semiconductor portion S1. Use of the main substrate 1 unlikely to melt with the seed 3 enables a configuration not provided with the buffer 2. The configuration is not limited to the configuration in which the seed 3 overlaps the entire mask portion 5 as illustrated in FIG. 16. Since the seed 3 may be exposed from the opening K, the seed 3 may be locally formed not to overlap a part or the entirety of the mask portion 5.

The opening K of the mask 6 has a function of a growth start hole for exposing the seed 3 and starting the growth of the first type semiconductor portion S1, and the mask portion 5 of the mask 6 has a function of a selective growth mask for growing the base semiconductor portion S11 in the lateral direction. The mask 6 may be a mask layer, and may be a mask pattern including the mask portion 5 and the opening K.

As the mask 6, for example, a single-layer film including any one of a silicon oxide film (SiOx), a titanium nitride film (TiN or the like), a silicon nitride film (SiNx), a silicon oxynitride film (SiON), and a metal film having a high melting point (e.g., 1000 degrees or more), or a layered film including at least two selected from the group consisting of them can be used.

For example, a silicon oxide film having a thickness of from about 100 nm to about 4 μm (preferably from about 150 nm to about 2 μm) is formed on the entire surface of the seed 3 by using sputtering, and a resist is applied onto the entire surface of the silicon oxide film. Subsequently, the resist is patterned by photolithography to form the resist with a plurality of openings having a stripe shape. Subsequently, a part of the silicon oxide film is removed by wet etchant such as hydrofluoric acid (HF) or buffered hydrofluoric acid (BHF) to form a plurality of the openings K, and the resist is removed by organic cleaning to form the mask 6. As another example, a silicon nitride film is formed by a sputtering device or a plasma enhanced chemical vapor deposition (PECVD) device. The silicon nitride film can withstand a film formation temperature (about 1000° C.) of a base semiconductor portion 8 even if the silicon nitride film is thinner than the silicon oxide film. The thickness of the silicon nitride film can be from about 5 nm to about 4 μm.

The openings K having a long shape (slit shape) can be periodically arrayed in the X direction. The width of the opening K may be from about 0.1 μm to about 20 μm. The smaller the width of the opening K is, the larger the width (size in the X direction) of a low defect portion SD (corresponding to the second portion B2 or the third portion B3) can be.

An abnormal portion such as a pinhole in the mask portion 5 may be eliminated by performing organic cleaning or the like after film formation and introducing the film again into a film forming device to form the same type of film. A typical silicon oxide film (single layer) can also be used to form the mask 6 having a good quality by such a method for forming the film again.

In Example 1, as an example of the template substrate 7, a silicon substrate (e.g., 2 inch Si substrate) having the (111) plane can be used for the main substrate 1, an AlN layer (about 30 nm to 300 nm, for example, 150 nm) can be used for the buffer 2, a GaN-based graded layer can be used for the seed 3, and a layered mask in which a silicon oxide film (SiO₂) and a silicon nitride film (SiN) are formed in this order can be used for the mask 6. The GaN-based graded layer may include an Al_{0.6}Ga_{0.4}N layer (e.g., 300 nm) that is a first layer and a GaN layer (e.g., from 1 to 2 m) that is a second layer. For the mask 6, a plasma chemical vapor deposition method (CVD method) can be used for formation of each of the silicon oxide film and the silicon nitride film, and the thickness of the silicon oxide film can be, for example, 0.3 μm and the thickness of the silicon nitride film can be, for example, 70 nm. The width (size in the X direction) of the mask portion 5 can be 50 μm, and the width (size in the X direction) of the opening K can be 5 μm.

### Base Semiconductor

Next, in Example 1, the base semiconductor portion S11 is formed on the template substrate 7 using the ELO method. In Example 1, the base semiconductor portion S11 is a GaN layer, and an ELO film of gallium nitride (GaN) is formed on the template substrate 7 using an MOCVD device. The following can be adopted as examples of the ELO film formation conditions: substrate temperature: 1120° C., growth pressure: 50 kPa, trimethylgallium (TMG): 22 sccm, NH₃: 15 slm, and V/III=6000 (ratio of group V raw material supply amount to group III raw material supply amount).

In this case, the base semiconductor portion S11 selectively grows (longitudinally grows) on the seed 3 (see FIG. 16) exposed to the opening K, and subsequently laterally grows on the mask portion 5. The lateral growth is stopped before GaN crystal films laterally growing from both sides on the mask portion 5 associate with each other. In Example 1, a plurality of the base semiconductor portions S11 is formed by stopping the growth before the semiconductor crystals (e.g., GaN-based crystals) growing to approach each other on the mask portion 5 associate with each other. Thus, the gap GP is formed between the base semiconductor portions S11 adjacent to each other in the X direction. The X direction may be the <11-20> direction (a-axis direction) of the GaN-based crystal, the Y direction may be the <1-100> direction (m-axis direction) of the GaN-based crystal, and the Z2 direction may be the <0001> direction (c-axis direction) of the GaN-based crystal.

In the formation of the base semiconductor portion S11 in Example 1, a longitudinal growth layer growing in the Z direction (c-axis direction) is formed on the seed 3 exposed from the opening K, and then a lateral growth layer growing in the X direction (a-axis direction) is formed. At this time, by setting the thickness of the longitudinal growth layer to 10 μm or less, 5 m or less, or 3 μm or less, the thickness of the lateral growth layer can be suppressed to be low, and the lateral film formation rate can be increased.

The threading dislocation density of the low defect portion SD (corresponding to the second portion B2 or the third portion B3) in the base semiconductor portion S11 may be ⅕ or less (e.g., 5×10⁶/cm² or less) of the threading dislocation density of a dislocation inheritance portion HD (corresponding to the first portion B1) in the base semiconductor portion S11. The threading dislocation density here can be obtained by performing CL measurement on the surface of the base semiconductor portion S11 (e.g., counting the number of black spots), for example. The dislocation density can be expressed in units of [quantity/cm²], and, in the present description, may be expressed as [/cm²] with the quantity omitted. The basal plane dislocation density of the low defect portion SD may be 5×10⁸/cm² or less. The basal plane dislocation may be a dislocation extending in the in-plane direction of the c-plane (X-Y plane) of the base semiconductor portion S11. Here, the basal plane dislocation density is obtained, for example, by splitting the base semiconductor portion S11 to expose the side surface of the low defect portion SD and performing CL measurement on the dislocation density of this side surface.

The lateral width (size in the X direction) of the base semiconductor portion S11 was 53 m, the width (size in the X direction) of the low defect portion SD was 24 μm, and the layer thickness (size in the Z direction) of the base semiconductor portion S11 was 5 μm. The aspect ratio of the base semiconductor portion S11 was 53 μm/5 μm=10.6, and a very high aspect ratio was achieved. The width of the mask portion 5 can be set in accordance with the specifications of the second type semiconductor portion S2 and the like (e.g., about 10 μm to 200 μm). In Example 1, the adjacent base semiconductor portions S11 do not associate with each other, the plurality of base semiconductor portions S11 having a bar shape is formed side by side in the X direction on the template substrate 7, and the lateral width (size in the X direction) of the gap GP was about 5 μm.

First Mold Portion, Active Portion, Second Type Semiconductor In the method for manufacturing the light-emitting element of Example 1, next, the first mold portion S12 is formed above the base semiconductor portion S11. Thus, the first type semiconductor portion S1 is formed. The first mold portion S12 may include, for example, a buffer layer (regrowth portion) containing an n-type GaN-based semiconductor. The first mold portion S12 can be formed by, for example, the MOCVD method. As described above, the first mold portion S12 includes the first contact S121, the first cladding portion S122, and the first light guide S123. For example, an n-type GaN layer can be used for the first contact S121, an n-type AlGaN layer can be used for the first cladding portion S122, and an n-type GaN layer can be used for the first light guide S123.

Then, the active portion AP is formed above the first type semiconductor portion S1. The active portion AP can be formed by, for example, the MOCVD method. For the active portion AP, for example, a multi-quantum well (MQW) structure including an InGaN layer can be used. The active portion AP may typically have an MQW structure of 5 to 6 periods.

In the method for manufacturing the light-emitting element of Example 1, the second type semiconductor portion S2 is formed to reach laterally the first type semiconductor portion S1 from above the active portion AP. The second type semiconductor portion S2 can be formed by, for example, the MOCVD method. As described above, the second type semiconductor portion S2 includes the second light guide S21, the electron blocking portion S22, the second light cladding portion S23, and the second contact S24. For example, a p-type GaN layer can be used for the second light guide S21, a p-type AlGaN layer can be used for the electron blocking portion S22, a p-type AlGaN layer can be used for the second light cladding portion S23, and a p-type GaN layer can be used for the second contact S24.

### Layered Body

Next, a ridge stripe structure, that is, the ridge RJ is formed using a photolithography method. Parts of the second type semiconductor portion S2, the active portion AP, and the first type semiconductor portion S1 may be engraved by etching or the like to expose a part of the upper surface of the first type semiconductor portion S1. The part where the surface in the first type semiconductor portion S1 is exposed may be, for example, the first contact S121. A side surface formed by engraving the first type semiconductor portion S1, the side surface of the first type semiconductor portion S1 being positioned on the opposite side in the X direction with respect to the first side surface FS of the first type semiconductor portion S1 is called a third side surface TS. The second side surface SS in the first type semiconductor portion S1 may be covered with the second type semiconductor portion S2, and the third side surface TS need not be covered with the second type semiconductor portion S2. The first side surface FS and the second side surface SS may be crystal planes, whereas the third side surface TS is a processed plane.

Then, after the insulating film DF is formed to partially cover the upper surface of the second type semiconductor portion S2 (to expose the ridge RJ), the first contact electrode E11 is formed on the second contact S24 of the ridge RJ. The first auxiliary electrode E12 is formed to cover the first contact electrode E11 and the insulating film DF. The second electrode E2 is formed on the upper surface of the part where the surface of the first type semiconductor portion S1 is exposed. The second electrode E2 may include the second contact electrode and the second auxiliary electrode (not illustrated).

For the first electrode E1 (anode) and the second electrode E2 (cathode), for example, a single-layer film or a multilayer film selected from (i) a metal film (that may be an alloy film) containing at least one selected from the group consisting of Ni, Rh, Pd, Cr, Au, W, Pt, Ti, and Al, and (ii) a conductive oxide film containing at least one selected from the group consisting of Zn, In, and Sn can be used. As the insulating film DF covering the ridge RJ, a single-layer film or a layered film containing an oxide or a nitride of, for example, Si, Al, Zr, Ti, Nb, or Ta can be used.

The first contact electrode E11 (p-contact electrode) may be, for example, a Pd film having a thickness of 50 nm. The first auxiliary electrode E12 may be a multilayer film in which, for example, a Ti film having a thickness of 100 nm, an Ni film having a thickness of 200 nm, and an Au film having a thickness of 100 nm are formed in this order. The second auxiliary electrode of the second electrode E2 may also have the same configuration as the first auxiliary electrode E12, and for example, a Ti film having a thickness of 100 nm may also serve as an n-contact electrode.

The insulating film DF, the first electrode E1, and the second electrode E2 may avoid a part where the open groove GS is formed, that is, a position where scribing is performed. The length in the Y direction of one insulating film DF, the length in the Y direction of one first electrode E1, and the length in the Y direction of one second electrode E2 may each be smaller than the resonator length L1.

In this manner, the layered body LB including the first type semiconductor portion S1, the second type semiconductor portion S2 including the ridge RJ, and the first electrode E1 and the second electrode E2 is formed. This can form the semiconductor substrate 10 including a plurality of layered bodies LB having a bar shape.

For example, the second electrode E2 may be formed on the base semiconductor portion S11 by engraving the second type semiconductor portion S2, the active portion AP, and the first type semiconductor portion S1 until, for example, the base semiconductor portion S11 in the first type semiconductor portion S1 is exposed.

### Laser Body

In the method for manufacturing the light-emitting element of Example 1, next, cleavage of the layered body LB (m-plane cleavage of the first and second type semiconductor portions S1 and S2 that are nitride semiconductor layers) is performed on the template substrate 7 to form the light emitter 20 having the pair of resonator end surfaces F1 and F2. When the layered body LB has a bar shape, for example, the layered body LB is cleaved in a direction (X direction) orthogonal to the long direction (Y direction) of the layered body LB. A plurality of pieces obtained by splitting the layered body LB can be the light emitter 20. Thus, a gap (open groove GS) is formed between the light emitters 20 adjacent to each other in the Y direction.

In Example 1, scribing (e.g., formation of a scribe groove serving as a cleavage starting point) may be performed on the layered body LB. A specific method for scribing is not particularly limited, but for example, scribing may be performed on the layered body LB by applying a force in an orientation parallel to the m-plane of the nitride semiconductor crystal in the second type semiconductor portion S2 using a scriber. The scriber may be a diamond scriber or may be a laser scriber.

In Example 1, the pair of resonator end surfaces F1 and F2 may be formed by cleavage that spontaneously proceeds by scribing the layered body LB. The base semiconductor portion S11 includes a GaN-based semiconductor, and the base substrate BK includes the main substrate 1 including a material having a thermal expansion coefficient smaller than that of the GaN-based semiconductor. For example, the base semiconductor portion S11 may contain GaN, and the base substrate BK may include an Si substrate or an SiC substrate.

When the base semiconductor portion S11 is formed on a dissimilar substrate such as an Si substrate by the ELO method, the film formation temperature is a high temperature of, for example, 1000° C. or higher, and the temperature is lowered to room temperature after the film formation, whereby an internal stress is generated in the base semiconductor portion S11. This internal stress is caused by, for example, a difference in thermal expansion coefficient between the main substrate 1 and the base semiconductor portion S11.

When the thermal expansion coefficient of the main substrate 1 is smaller than the thermal expansion coefficient of the base semiconductor portion S11, tensile stress is generated in the base semiconductor portion S11. For example, since the main substrate 1 is an Si substrate and the constituent material of the base semiconductor portion S11 is GaN, tensile stress is generated in the base semiconductor portion S11. Due to a lattice constant difference between the main substrate 1 and the base semiconductor portion S11, strain is generated in the base semiconductor portion S11, whereby the internal stress can be generated in the base semiconductor portion S11. When such the layered body LB is scribed, the internal stress of the base semiconductor portion S11 is released and tensile strain is generated at the cleavage origin, whereby cleavage spontaneously proceeds.

For example, by scribing the layered body LB at intervals of 100 μm in the long direction of the layered body LB, the resonator length L1 of the light emitter 20 can be 100 μm. By performing scribing, the cleavage of the layered body LB spontaneously proceeds due to the internal stress of the base semiconductor portion S11, and the layered body LB can be separated into the plurality of individual light emitters 20. At this time, the main substrate 1 is not split. The mask portion 5 need not be split, and may be split due to the influence of cleavage of the layered body LB. In the part of the opening K of the mask 6, the base semiconductor portion S11 of each layered body LB and the base substrate BK are chemically bonded. Therefore, the light emitter 20 is held on the base substrate BK, and the position is maintained on the base substrate BK.

In Example 1, by forming the light emitter 20 by cleavage, the volume of the layered body LB to be lost can be reduced as compared with the case where the open groove GS is formed by, for example, dry etching. Therefore, the semiconductor substrate 10 can be efficiently used (as an element).

In Example 1, since the resonator end surfaces F1 and F2 are formed by m-plane cleavage, planarity and perpendicularity to the c-plane (parallelism of the resonator end surfaces F1 and F2) are excellent, and high light reflectance can be obtained by high reflection film coating. Accordingly, mirror loss can be reduced even with a short resonator length of 200 μm or less at which mirror loss increases, and stable laser oscillation is possible even with a short resonator length of 200 μm or less at which optical gain decreases. Since the resonator end surfaces F1 and F2 at the position corresponding to the light emission region EA are formed on the second portion B2, which is the low defect portion SD, the planarity of the cleavage plane is excellent, and high light reflectance is achieved.

### Support Substrate

The method for manufacturing the light-emitting element in Example 1 includes preparing the support substrate SK. A specific configuration of the support substrate SK to be prepared is not particularly limited as long as the light emitter 20 can be junction-down mounted, but an example will be described below. FIG. 17 is a plan view illustrating an example of the configuration of the support substrate.

As illustrated in FIG. 17, the support substrate SK includes the first pad P1 and the second pad P2 having conductivity and T shape, a first bonding material CA1 that functions as a bonding layer with the first pad P1, and a second bonding material CA2 that functions as a bonding layer with the second pad P2. Examples of the material of a substrate body BS in the support substrate SK include Si, SiC, and AlN. The first bonding material CA1 and the second bonding material CA2 correspond to the bonding material CA described above, and may include a conductive material having at least one selected from the group consisting of heating fluidity, pressure curability, a thermosetting property, and photocurability. The first bonding material CA1 and the second bonding material CA2 may be, for example, solder.

In Example 1, for example, the support substrate SK may be formed as follows. That is, a 4-inch Si substrate is used as the substrate body BS, and the first pad P1 and the second pad P2 are formed by a wafer process using a photolithography technique. A plurality of recesses HL (rectangular in plan view) can be provided in a matrix with a depth of 100 μm by reactive ion etching (RIE) or the like. Then, the first bonding material CA1 and the second bonding material CA2 are formed. Each of the first pad P1 and the second pad P2 may be a multilayer film in which a Cr film having a thickness of 10 nm, a Pt film having a thickness of 25 nm, and an Au film having a thickness of 100 nm are formed in this order from the substrate body BS side. The first bonding material CA1 may be, for example, an AuSn bonding layer in which an AuSn film having a thickness of 3000 nm and an Au film having a thickness of 100 nm are formed in this order from the substrate body BS side. In Example 1, the second bonding material CA2 may include the same material as the first bonding material CA1, and may be thicker than the first bonding material CA1.

The material of the substrate body BS in the support substrate SK and the material of the base substrate BK in the semiconductor substrate 10 may be homogeneous, and may be Si, for example. In this case, the thermal expansion coefficient of the support substrate SK can be made equal to the thermal expansion coefficient of the semiconductor substrate 10. This can improve the accuracy of alignment between the support substrate SK and the semiconductor substrate 10, and reduce the possibility of occurrence of a defect in transfer due to the influence of temperature change by heating and cooling when selective transfer is performed.

### Light-Emitting Element

In Example 1, after the light emitter 20 is formed, the mask portion 5 may be removed by etching using hydrofluoric acid, buffered hydrofluoric acid (BHF), or the like. That is, the mask portion 5 of the semiconductor substrate 10 may be removed before the junction-down mounting on the support substrate SK. This can easily separate the light emitter 20 from the template substrate 7. Since the semiconductor substrate 10 has the gap GP, the mask portion 5 is partially exposed. Therefore, the mask portion 5 can be easily removed by etching.

The semiconductor substrate 10 may be split into an appropriate size by dicing or the like, and for example, may be split into small pieces of 10 mm square size. The support substrate SK may be split into an appropriate size by dicing or the like, and for example, the support substrate SK may be split into small pieces of 10 mm square size, which is the same size as the semiconductor substrate 10 having been split into small pieces.

Thereafter, in the method for manufacturing the light-emitting element in Example 1, the light emitter 20 is junction-down mounted on the support substrate SK. For example, a part selected from the plurality of light emitters 20 may be selectively transferred from the semiconductor substrate 10 to the support substrate SK to straddle the plurality of light emitters 20, such as every 2 or 3 light emitters. In the semiconductor substrate 10, on the template substrate 7, the light emitters 20 are individually separated by having the gap GP between the light emitters 20 and the open groove GS. Therefore, selective transfer can be easily performed.

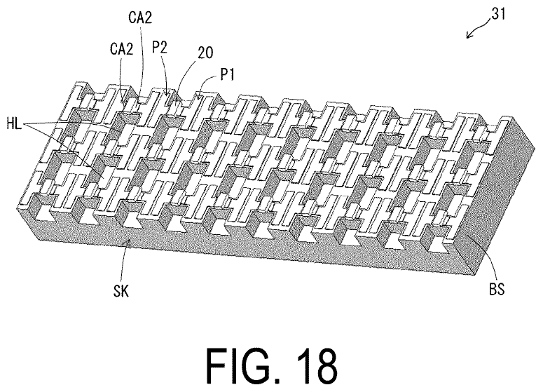

FIG. 18 is a perspective view schematically illustrating a light-emitting substrate (semiconductor laser array) with a plurality of light emitters being bonded to the support substrate. A light-emitting substrate 31 includes the support substrate SK and the plurality of light emitters 20. In the light-emitting substrate 31, the plurality of light emitters 20 may be arranged on the support substrate SK in a matrix in a direction (Y direction) defining the resonator length and a direction (X direction) orthogonal thereto, and thus the directions of the resonator lengths are aligned.

Next, the reflecting mirror film UF is formed on the resonator end surfaces F1 and F2 of the light emitter 20. The reflecting mirror film UF is formed for reflectance adjustment, passivation, and the like. The reflecting mirror film UF may be formed by using the light-emitting substrate 31 of a two-dimensional arrangement type, or the reflecting mirror film UF may be formed by dividing the light-emitting substrate 31 into a bar shape and then using the light-emitting substrate 31 having a bar shape that is formed.

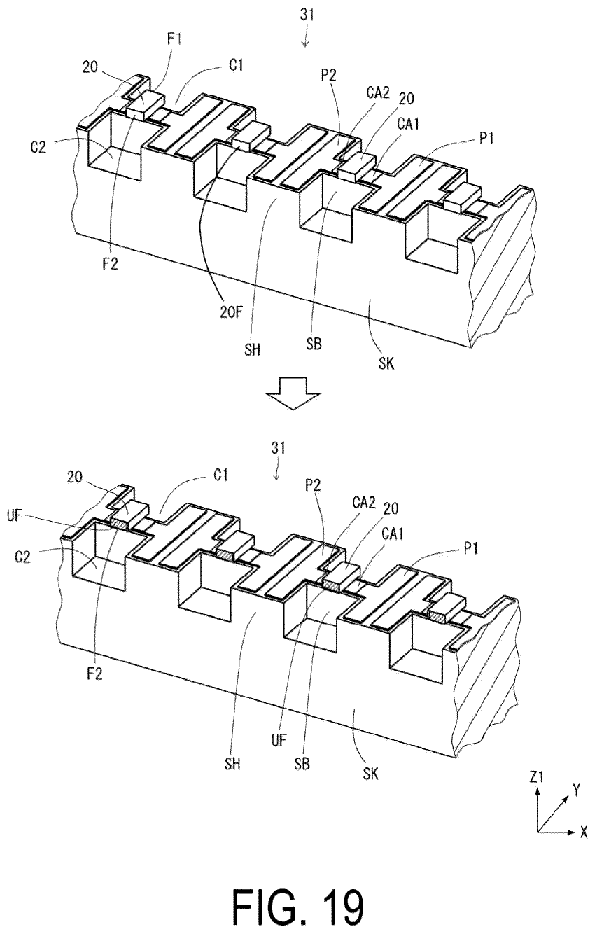

FIG. 19 is a perspective view illustrating an example of the light-emitting substrate having a bar shape after division. The light-emitting substrate 31 of the two-dimensional arrangement type as illustrated in FIG. 18 can be laterally split (split for each row extending in the X direction) to form the light-emitting substrate 31 of a one-dimensional arrangement type (bar-shaped) as illustrated in FIG. 19. The one-dimensional arrangement type facilitates formation of the reflecting mirror film UF to the pair of resonator end surfaces F1 and F2.

The support substrate SK includes a wide portion SH and a placement portion SB. The light emitter 20 is positioned above the placement portion SB, and thus the width direction (Y direction) of the placement portion SB coincides with the direction of the resonator length. In the light-emitting substrate 31, the pair of resonator end surfaces F1 and F2 of the light emitter 20 may protrude from the placement portion SB in plan view. The placement portion SB is formed between two cutouts C1 and C2 facing each other in the direction (Y direction) defining the resonator length, the resonator end surface F1 is positioned on the cutout C1, and the resonator end surface F2 is positioned on the cutout C2. The cutouts C1 and C2 are parts corresponding to the recesses HL in the support substrate SK before being divided. The shape of the cutouts C1 and C2 can be, for example, rectangular in plan view viewed in the Z1 direction. Since the support substrate SK is provided with the cutouts C1 and C2, the reflecting mirror film UF is easily formed on the pair of resonator end surfaces F1 and F2. It is possible to effectively reduce the possibility that the first bonding material CA1 goes up on the end surface 20F (see FIG. 2) of the light emitter 20.

Thereafter, the light-emitting substrate 31 may be further divided. Thus, a plurality of the light-emitting elements 30 can be formed, in which one or more light emitters 20 are junction-down mounted on the support body ST.

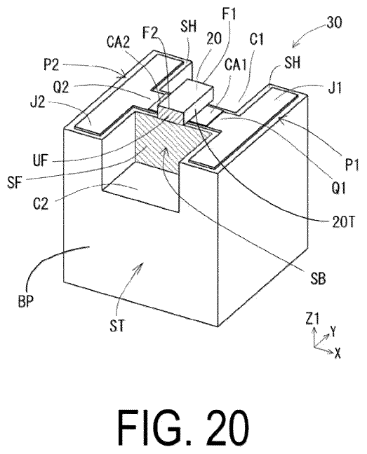

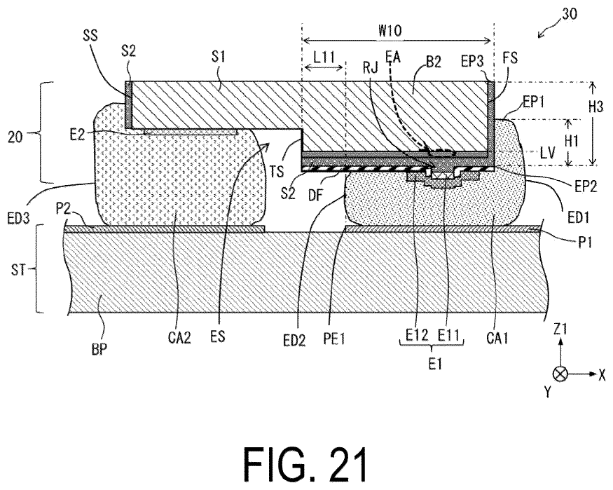

FIG. 20 is a perspective view illustrating the configuration of the light-emitting element in Example 1. FIG. 21 is a cross-sectional view illustrating a configuration of the light-emitting element in Example 1. As illustrated in FIGS. 20 and 21, the light-emitting element 30 includes the light emitter 20, the first bonding material CA1 and the second bonding material CA2, and the support body ST supporting the light emitter 20 via the first and second bonding materials CA1 and CA2, and thus the first type semiconductor portion S1 is positioned higher than the active portion AP.

The support body ST includes the first pad P1 and the second pad P2 that are conductive, the first electrode E1 is connected to the first pad P1 via the first bonding material CA1, and the second electrode E2 is connected to the second pad P2 via the second bonding material CA2. The base portion BP, which is the body of the support body ST, corresponds to a part in which the substrate body BS in the support substrate SK is split. The second bonding material CA2 may be thicker than the first bonding material CA1, and the difference in thickness between the first bonding material CA1 and the second bonding material CA2 may be equal to or greater than the thickness of the second type semiconductor portion S2. This can easily bond the first and second electrodes E1 and E2 and the first and second pads P1 and P2 positioned on the same plane. The light-emitting element 30 functions as a chip on submount (COS).

The first pad P1 includes a mounting portion J1 positioned on the wide portion SH and having a length in the Y direction larger than the resonator length L1, and a contact Q1 positioned on the placement portion SB and having a length in the Y direction smaller than the resonator length L1. The second pad P2 includes a mounting portion J2 positioned on the wide portion SH and having a length in the Y direction larger than the resonator length L1, and a contact Q2 positioned on the placement portion SB and having a length in the Y direction smaller than the resonator length L1. The contacts Q1 and Q2 are arranged in the X direction on the upper surface of the placement portion SB, the first bonding material CA1 is formed on the contact Q1, and the second bonding material CA2 is formed on the contact Q2. The first bonding material CA1 is in contact with the first electrode E1 of the light emitter 20, and the second bonding material CA2 is in contact with the second electrode E2 of the light emitter 20. Solders such as AuSi and AuSn can be used as materials of the first bonding material CA1 and the second bonding material CA2.

Although the resonator end surfaces F1 and F2 of the light emitter 20 are covered with the reflecting mirror film UF, a dielectric film SF including the same material as the reflection mirror film UF may be formed on a surface (e.g., the side surface of the placement portion SB) parallel to the resonator end surfaces F1 and F2 among the side surfaces of the support body ST.

For example, when the light emitter 20 is junction-down mounted from the semiconductor substrate 10 to the support substrate SK, the semiconductor substrate 10 and the support substrate SK are brought into contact with each other and applied with a load. Then, the first bonding material CA1 and the second bonding material CA2 are melted, held for a certain period of time, and then cooled to room temperature. This brings the semiconductor substrate 10 and the support substrate SK into a state of being bonded to each other. Specifically, the first electrode E1 and the first pad P1 are bonded by the first bonding material CA1, and the second electrode E2 and the second pad P2 are bonded by the second bonding material CA2. Thereafter, by applying an external force and thus moving the semiconductor substrate 10 and the support substrate SK away from each other, the light emitter 20 that is expected among the plurality of light emitters 20 on the semiconductor substrate 10 is selectively transferred to the support substrate SK.

The first bonding material CA1 and the second bonding material CA2 having fluidity wet and spread on the first pad P1 and the second pad P2, and can go up on the side surface 20T of the light emitter 20. The light-emitting element 30 may have apart of the edge ED1 of the first bonding material CA1 protruding from the light emitter 20 in plan view in which the light-emitting element 30 is viewed in the layering direction of the first type semiconductor portion S1 and the active portion AP. In Example 1, since the light emitter 20 has a single-sided two-electrode structure, the first bonding material CA1 easily protrudes outward in the X direction from the light emitter 20 in plan view.

In the light-emitting element 30 in Example 1, the first bonding material CA1 goes up along the second type semiconductor portion S2 positioned laterally on the first side surface FS. The go-up height H1 of the first bonding material CA1 may exceed the lower surface level LV of the first type semiconductor portion S1. In the light emitter 20, the second type semiconductor portion S2 reach laterally the first side surface FS of the first type semiconductor portion S1 from below the active portion AP. The light-emitting element 30 has the formation height H3 of the second type semiconductor portion S2 larger than the go-up height H1 of the bonding material CA. This enables the light-emitting element 30 to effectively reduce the possibility that the first bonding material CA1 and the first type semiconductor portion S1 come into contact with each other even when the first bonding material CA1 goes up along the first side surface FS.

In the light-emitting element 30, a width W10 in the X direction may be 50 μm or less, or may be 20 μm or less. The width W10 may be a distance in the X direction between the third side surface TS and the outer surface of the second type semiconductor portion S2 positioned laterally on the first side surface FS. The light-emitting element 30 may have a distance L11 in the X direction between the third side surface TS and an end surface PE1 of the first pad P1, and in this case, the first bonding material CA1 can be made hardly go up the third side surface TS. At least a part of the third side surface TS may be covered with the insulating film DF, and at least a part of the third side surface TS may be in contact with the insulating film DF.

The first type semiconductor portion S1 has the second portion (wing portion) B2 closer to the first side surface FS than the first portion (center portion) B1 in the X direction (a-axis direction of the nitride semiconductor crystal) and smaller in threading dislocation density than the first portion B1. In the light-emitting element 30, the ridge RJ overlaps the second portion B2 in plan view, and each of the pair of resonator end surfaces F1 and F2 is an m-plane of a nitride semiconductor. The active portion AP includes the light emission region (light-emitting section) EA positioned below the second portion B2.

In Example 1, the first type semiconductor portion S1 includes an exposure section ES in which the second type semiconductor portion S2 is not positioned below. The exposure section ES may be a part formed by engraving a part of the first type semiconductor portion S1. The light-emitting element 30 is provided with the first electrode (anode) E1 below the second type semiconductor portion S2, and is provided with the second electrode (cathode) E2 below the exposure section ES.

In the light-emitting element 30, the second type semiconductor portion S2 may reach laterally the first side surface FS in the first type semiconductor portion S1 from the lower side of the active portion AP and reach laterally the second side surface SS, and the second bonding material CA2 may go up along the second type semiconductor portion S2 positioned laterally on the second side surface SS. The light-emitting element 30 may have a part of the edge ED3 protruding from the light emitter 20 in plan view, the edge ED3 on the side farther from the first side surface FS among the two ends of the second bonding material CA2 in the width direction (X-axis direction). In the light-emitting element 30, the third side surface TS, which is a side surface positioned on the exposure section ES side, is a surface formed by etching or the like, and need not be covered with the second type semiconductor portion S2.

### Another Configuration Example 1

### (1A)

In Example 1, the open groove GS is formed by cleaving the layered body LB, and the layered body LB is split into the plurality of light emitters 20. The present invention is not limited to this, and the open groove GS may be formed by forming a plurality of trenches in the layered body LB, and the layered body LB may be split into a plurality of light emitters 20.

For example, the plurality of trenches as the open groove GS can be formed by performing dry etching on the layered body LB. This can form the pair of resonator end surfaces F1 and F2 (etched mirrors). The trench may be formed after the first electrode E1 and the second electrode E2 are formed, or the first electrode E1 and the second electrode E2 may be formed after the trench is formed.

### (1B)

In another example of the light-emitting element 30, the active portion AP may reach laterally the first type semiconductor portion S1 from below the first type semiconductor portion S1, and the active portion AP may cover at least a part of the first side surface FS. The active portion AP may cover at least a part of the second side surface SS of the first type semiconductor portion S1.

When the active portion AP is formed on the first type semiconductor portion S1, the first side surface FS and the second side surface SS can be supplied with the raw material of the active portion AP. Since the active portion AP has a thin film thickness, it is difficult to form the active portion AP on the surfaces of the first side surface FS and the second side surface SS in the first type semiconductor portion S1, but the active portion AP can exist between the first side surface FS and the second type semiconductor portion S2 or between the second side surface SS and the second type semiconductor portion S2.

### (1C)

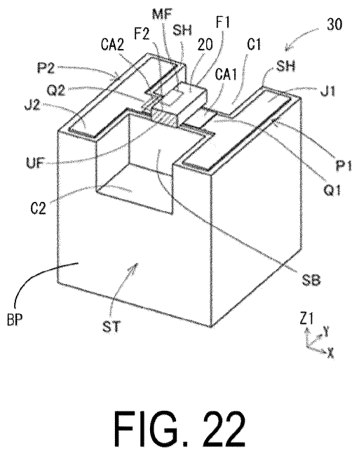

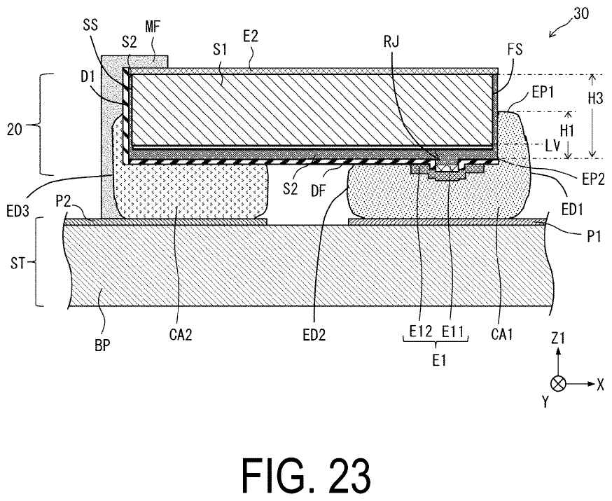

In another example of the light-emitting element 30, the light emitter 20 may be a laser body (semiconductor laser chip) having a double-sided electrode structure. FIG. 22 is a perspective view illustrating a configuration of a light-emitting element in another example of Example 1. FIG. 23 is a cross-sectional view illustrating a configuration of the light-emitting element in another example of Example 1.

As illustrated in FIGS. 22 and 23, in the light-emitting element 30 in another example of Example 1, the first electrode (anode) E1 may be provided below the second type semiconductor portion S2, and the second electrode (cathode) E2 may be provided above the first type semiconductor portion S1. In the light-emitting element 30, the light emitter 20 need not include the exposure section ES. The insulating film DF may cover the lower surface of the second type semiconductor portion S2. The second bonding material CA2 may be solder or a material having no conductivity. The edge ED3 of the second bonding material CA2 may protrude from the light emitter 20 in plan view. When the second bonding material CA2 has conductivity, the insulating film D1 may be formed to cover the second side surface SS of the first type semiconductor portion S1 and the side surfaces of the active portion AP and the second type semiconductor portion S2. When the second bonding material CA2 does not have conductivity, the insulating film D1 need not be formed. The second electrode E2 formed on the back surface (the surface on the side far from the support body ST) of the first type semiconductor portion S1 may be connected to the second pad P2 via a conductive film MF, for example. The second electrode E2 may be wire-bonded to the second pad P2.

### (1D)

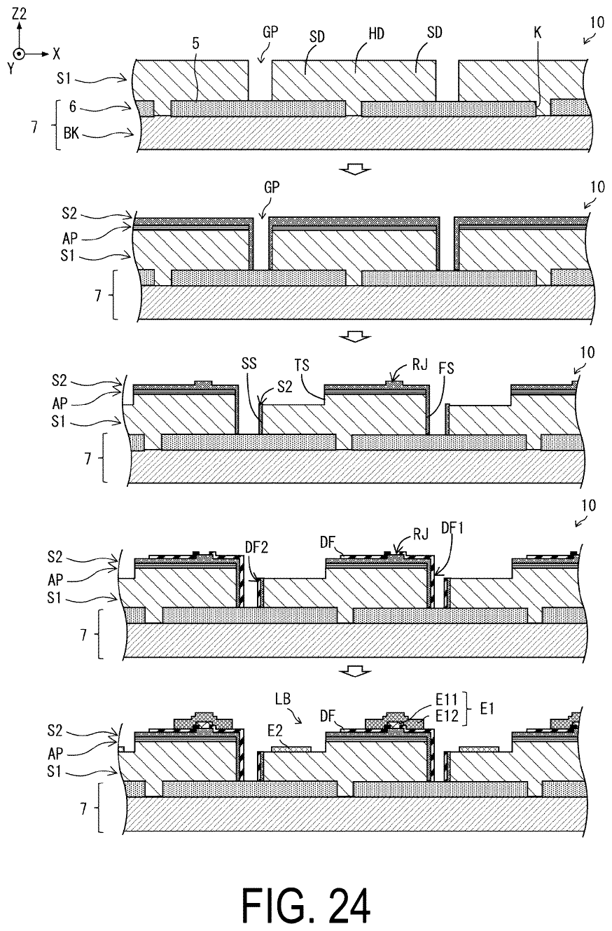

FIG. 24 is a cross-sectional view schematically illustrating a method for manufacturing the light-emitting element in another example of Example 1. As illustrated in FIG. 24, in another example of Example 1, when the insulating film DF is formed to cover the side surface of the ridge RJ, for example, the insulating film DF may be formed to reach laterally the first type semiconductor portion S1 from above the second type semiconductor portion S2. The light-emitting element 30 in another example of Example 1 may include a first insulating film DF1 covering a part of the second type semiconductor portion S2 wrapping around the first side surface FS. The first insulating film DF1 may be in contact with the second type semiconductor portion S2. As described above, in the first side surface FS, there may be a part where the second type semiconductor portion S2 is not positioned on the first side surface FS. In this case, there may be a part where the second type semiconductor portion S2 does not exist between the first insulating film DF1 and the first side surface FS, and the first insulating film DF1 may be in contact with the first side surface FS in this part.

A second insulating film DF2 may be formed to cover a part of the second type semiconductor portion S2 wrapping around the second side surface SS. The second type semiconductor portion S2 need not exist between the second insulating film DF2 and the second side surface SS, and the second insulating film DF2 may be in contact with the second side surface SS in the portion.

The first insulating film DF1 may be formed separately from the insulating film DF after the insulating film DF is formed above the second type semiconductor portion S2. The first insulating film DF1 can be formed before the light emitter 20 is transferred to the support substrate SK. The second insulating film DF2 may be formed at the same timing as the first insulating film DF1, or the second insulating film DF2 need not be formed.

The insulating film DF may reach the third side surface TS from above the second type semiconductor portion S2. Even when the first bonding material CA1 goes up on the third side surface TS, it is possible to effectively reduce the possibility that the first bonding material CA1 comes into contact with the first type semiconductor portion S1.

Although not illustrated, also when the light emitter 20 has a double-sided electrode structure, the first insulating film DF1 and the second insulating film DF2 can be formed by the same flow as described above.

The following effects are also achieved. For example, when dry etching is performed on a certain layered body LB, the influence of dry etching may occur on the adjacent layered body LB due to a factor such as insufficient protection by a resist. When the first side surface FS is covered only with the second type semiconductor portion S2, the first type semiconductor portion S1 can be exposed due to the influence of dry etching. On the other hand, by forming the insulating film DF or the first insulating film DF1 on the first side surface FS, it is possible to effectively reduce the possibility of occurrence of an unintended influence by dry etching.

### (1E)

When the base semiconductor portion S11 is formed using the ELO method, the template substrate 7 including the main substrate 1 and the mask 6 on the main substrate 1 may be used, and the template substrate 7 may include a growth suppression region (e.g., a region in which crystal growth in the Z direction is suppressed) corresponding to the mask portion 5 and a seed region corresponding to the opening K. For example, the base semiconductor portion S11 can be formed using the ELO method on a template substrate including the growth suppression region and the seed region.

### Example 2

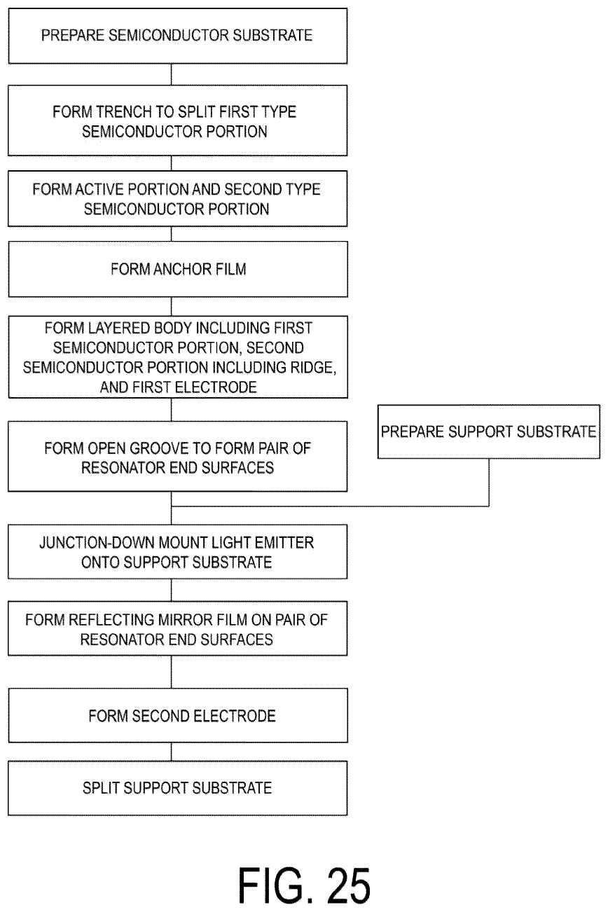

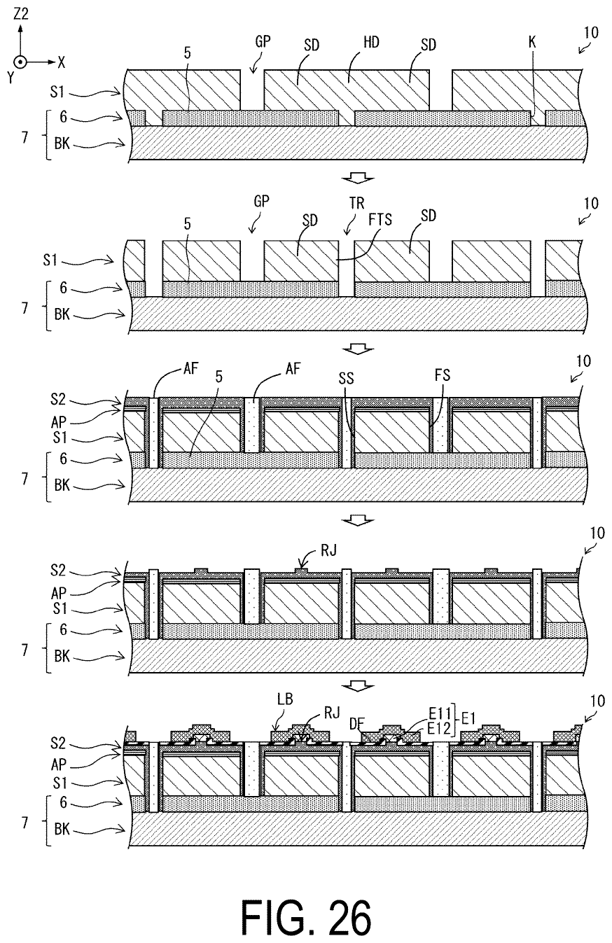

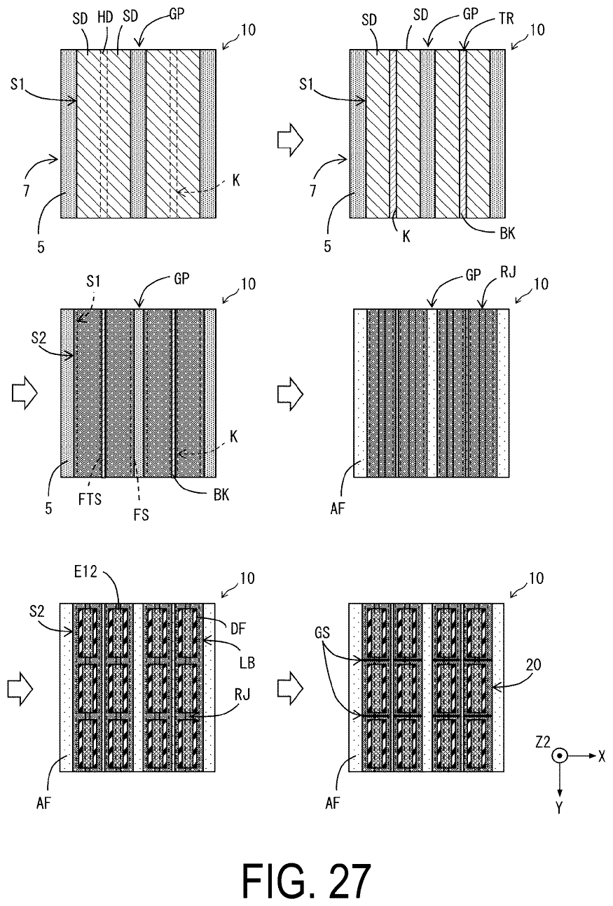

FIG. 25 is a flowchart schematically showing a method for manufacturing a light-emitting element in Example 2. FIG. 26 is a cross-sectional view schematically illustrating a method for manufacturing the light-emitting element in Example 2. FIG. 27 is a plan view schematically illustrating a method for manufacturing the light-emitting element in Example 2.

In Example 1, the layered body LB is formed by forming the second type semiconductor portion S2 on the first type semiconductor portion S1 having the low defect portion SD and the dislocation inheritance portion HD. In Example 2, a part (dislocation inheritance portion HD) on the opening K in the first type semiconductor portion S1 formed on the template substrate 7 is removed, and the second type semiconductor portion S2 is formed on the first type semiconductor portion S1 having the low defect portion SD. In Example 2, an example in which the light emitter 20 having a double-sided electrode structure is formed will be described, but the light emitter 20 having a single-sided two-electrode structure can also be formed as described above. For example, it is also possible to form the light emitter 20 having a single-sided two-electrode structure using the low defect portion SD by forming the first type semiconductor portion S1 with a lateral width.

As illustrated in FIGS. 25 to 27, first, the semiconductor substrate 10 is prepared. The semiconductor substrate 10 may include the plurality of first type semiconductor portions S1 having a bar shape formed by stopping the growth before a plurality of semiconductor crystals (e.g., GaN-based crystals) growing to approach each other on the mask portion 5 associates with each other.

A plurality of trenches TR is formed in the first type semiconductor portion S1 by etching to remove a bonding portion between the first type semiconductor portion S1 and the base substrate BK of the template substrate 7 (e.g., a bonding portion with the seed 3: see FIG. 16). This splits the first type semiconductor portion S1. The trench TR may extend in the long direction (Y direction) of the opening K. In Example 2, a fourth side surface FTS, which is one of the two side surfaces facing each other in the a-axis direction of the first type semiconductor portion S1, may be formed by the trench TR.

In Example 2, since the first type semiconductor portion S1 is gently bonded to the mask portion 5, an anchor film AF may be formed, and thus the position of the layered body LB does not change on the template substrate 7 after the active portion AP and the second type semiconductor portion S2 are formed.

The anchor film AF is in contact with the side surface of the second type semiconductor portion S2 or the side surface of the first type semiconductor portion S1, and the mask portion 5, and anchors the layered body LB to the template substrate 7. As the anchor film AF, a dielectric film and the like such as a silicon oxide film, a silicon nitride film, an aluminum oxide film, a silicon oxynitride film, an aluminum oxide-silicon film, an aluminum oxynitride film, a zirconium oxide film, a titanium oxide film, and a tantalum oxide film can be used.

At the time of selective transfer of the light emitter 20 in a subsequent process, at least a part of the anchor film AF may remain on the template substrate 7 or may be attached to the light emitter 20. The anchor film AF has no electrical conductivity, and therefore, even if the anchor film AF finally remains on a chip, there is no possibility that the anchor film AF causes electrical leakage or the like.

Next, the second type semiconductor portion S2 including the active portion AP and the ridge RJ is formed above the first type semiconductor portion S1. The second type semiconductor portion S2 may be in contact with at least a part of the fourth side surface FTS. After the insulating film DF is formed on the ridge RJ, the first electrode E1 is formed. The open groove GS is formed in the layered body LB. Thus, the layered body LB is split into the plurality of light emitters 20. The open groove GS may be a gap space generated by cleavage or may be the trench TR. The subsequent processes may be the same as those in the first embodiment and another configuration example 1C described above. The anchor film AF and the mask portion 5 may be removed before the light emitter 20 is junction-down mounted on the support substrate SK. When the anchor film AF is positioned to cover the first side surface FS, it is possible to effectively reduce the possibility that the first bonding material CA1 and the first side surface FS come into contact with each other.

### Another Configuration Example 2

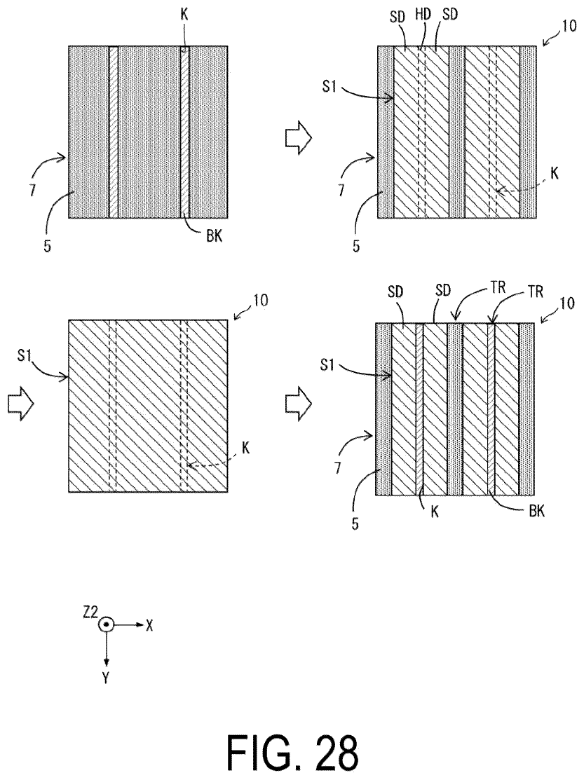

FIG. 28 is a plan view schematically illustrating a method for manufacturing a light-emitting element in another example of Example 2. In another configuration example of Example 2, after the first type semiconductor portion S1 is formed in a planar shape using the ELO method, the plurality of first type semiconductor portions S1 having a bar shape may be formed by etching or the like. As illustrated in FIG. 28, the first type semiconductor portion S1 is formed by the ELO method on the template substrate 7 that is prepared. In another configuration example of Example 2, semiconductor crystals (e.g., GaN-based crystals) growing to approach each other on the mask portion 5 associate with each other on the mask portion 5, and then the growth is stopped. Thereafter, the semiconductor crystals in the association part are removed, thereby forming the plurality of first type semiconductor portions S1.

The association occurs substantially at the center of the adjacent opening K (the center portion of the mask portion 5). By forming the plurality of trenches TR extending in the Y direction with respect to the first type semiconductor portion S1 having a planar shape in plan view, the plurality of first type semiconductor portions S1 having a bar shape is formed. The dislocation inheritance portion HD may or need not be removed by the trench TR. The trench TR may be formed with the mask portion 5 removed and the base substrate BK exposed in plan view, or may be formed with the mask portion 5 remaining. The subsequent processes may be the same as those in Example 2 described above.

### Example 3

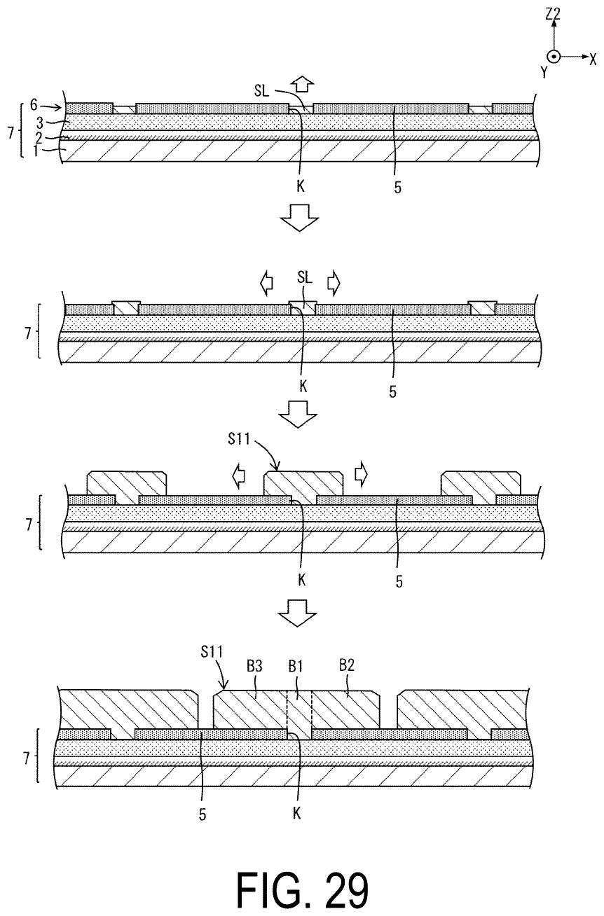

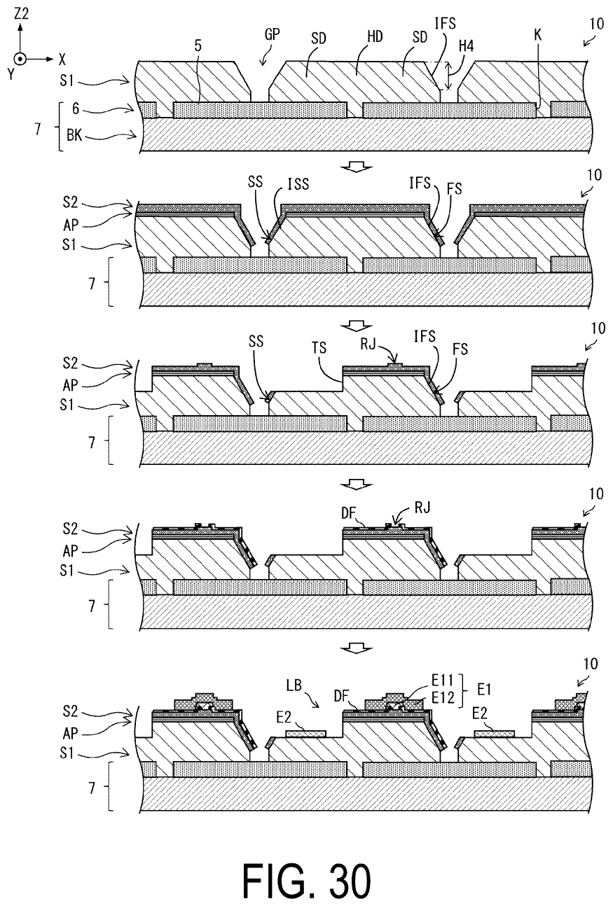

FIG. 29 is a cross-sectional view illustrating an example of lateral growth of the base semiconductor portion. FIG. 30 is a cross-sectional view schematically illustrating a method for manufacturing a light-emitting element in Example 3.

The base semiconductor portion S11 formed by the ELO method can be laterally grown as follows. As illustrated in FIG. 29, an initial growth portion SL may be formed on the seed 3 (GaN layer of an upper layer) exposed from the opening K, and then the base semiconductor portion S11 may be laterally grown from the initial growth portion SL. The initial growth portion SL serves as a starting point of the lateral growth of the base semiconductor portion S11. By appropriately controlling the ELO film formation conditions, it is possible to perform control of growing the base semiconductor portion S11 in the Z direction (c-axis direction) or in the X direction (a-axis direction).

Here, the film formation of the initial growth portion SL may be stopped at a timing immediately before the edge of the initial growth portion SL rides on the upper surface of the mask portion 5 (a stage of being in contact with the upper end of the side surface of the mask portion 5) or immediately after the edge of the initial growth portion SL rides on the upper surface of the mask portion 5 (i.e., at this timing, the ELO film formation condition may be switched from a c-axis direction film formation condition to an a-axis direction film formation condition). In this way, since the lateral film formation is performed from the state in which the initial growth portion SL slightly protrudes from the mask portion 5, it is possible to reduce consumption of the material for the growth in the thickness direction of the base semiconductor portion S11 and to laterally grow the base semiconductor portion S11 at a high speed. The initial growth portion SL can have a thickness of, for example, 0.5 m or more and 4.0 μm or less.

In Example 3, as illustrated in FIG. 30, a first inclined surface IFS inclined toward the ridge RJ may be included on the first side surface FS, which is a side surface closer to the ridge RJ in the first type semiconductor portion S1. The second type semiconductor portion S2 may cover the first inclined surface IFS. The second side surface SS of the first type semiconductor portion S1 may include a second inclined surface ISS inclined toward the ridge RJ. The second type semiconductor portion S2 may cover the second inclined surface ISS.

In Example 3, by having the first inclined surface IFS, the second type semiconductor portion S2 easily reaches laterally the first type semiconductor portion S1 from above the active portion AP. It is easy to form the insulating film DF reaching laterally the first type semiconductor portion S1 from above the second type semiconductor portion S2. In Example 3, the insulating film DF may reach laterally the first type semiconductor portion S1 from above the second type semiconductor portion S2, and in this case, the insulating film DF may be positioned above a normal direction of at least a part of the first inclined surface IFS. The insulating film DF may cover at least a part of the second type semiconductor portion S2 formed on the first inclined surface IFS. The first insulating film DF1 formed separately from the insulating film DF may cover at least a part of the first inclined surface IFS.

The first inclined surface IFS may be a crystal plane, may be the (11-22) plane of a nitride semiconductor crystal, for example, and may be a (11-2β) plane (β is an integer). A height H4 of the first inclined surface IFS in the Z2-axis direction may be 0.1 times or more and 0.9 times or less the height H11 (see FIG. 11) of the first type semiconductor portion S1. The first inclined surface IFS is not limited to a crystal plane, and may be a processed plane.

In Example 3, since the first type semiconductor portion S1 includes the first inclined surface IFS, the insulating film DF can be easily formed to reach the first inclined surface IFS. Since the insulating film DF reaches the first inclined surface IFS, it is possible to effectively reduce the possibility of occurrence of an unintended influence on the layered body LB due to dry etching. As a result, when the light emitter 20 is junction-down mounted on the support substrate SK, it is possible to effectively reduce the possibility that the first electrode E1 and the first type semiconductor portion S1 are short-circuited via the first bonding material CA1.

### Example 4

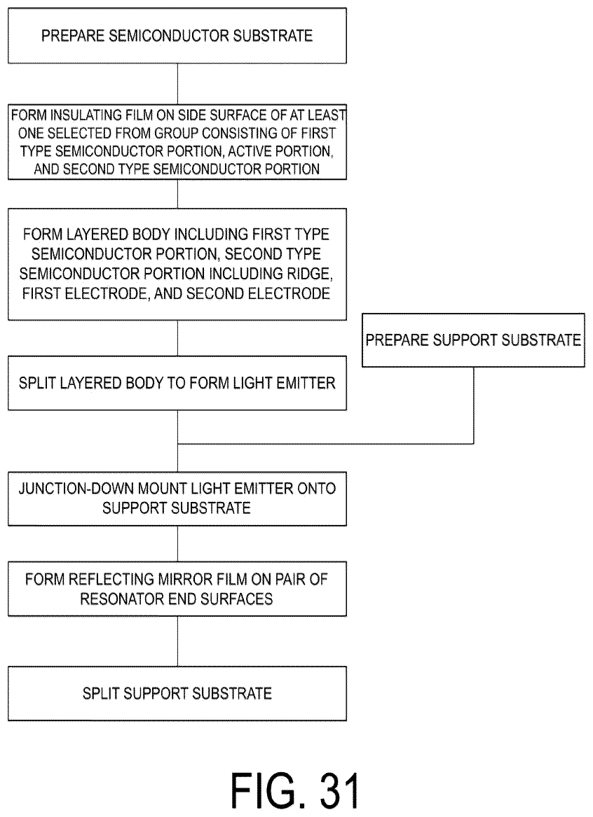

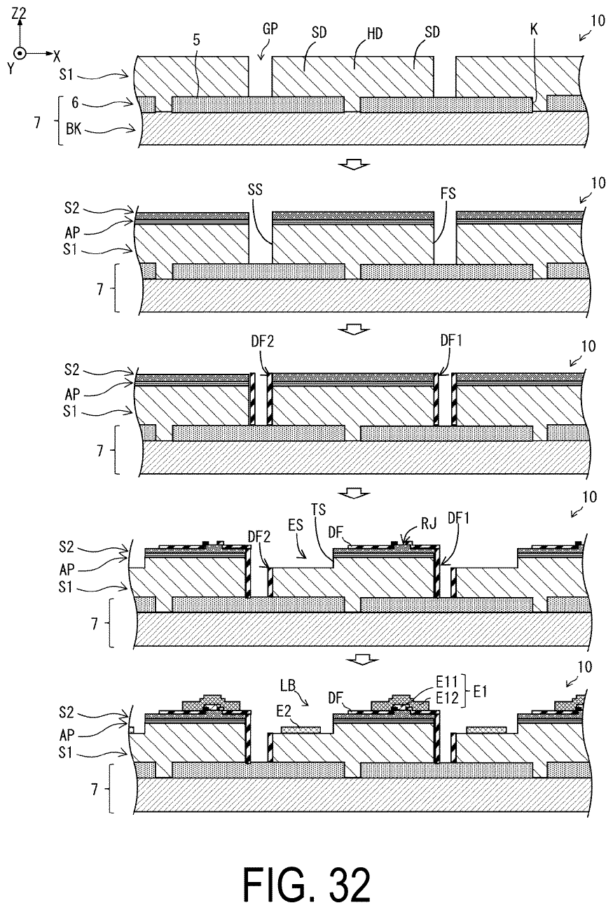

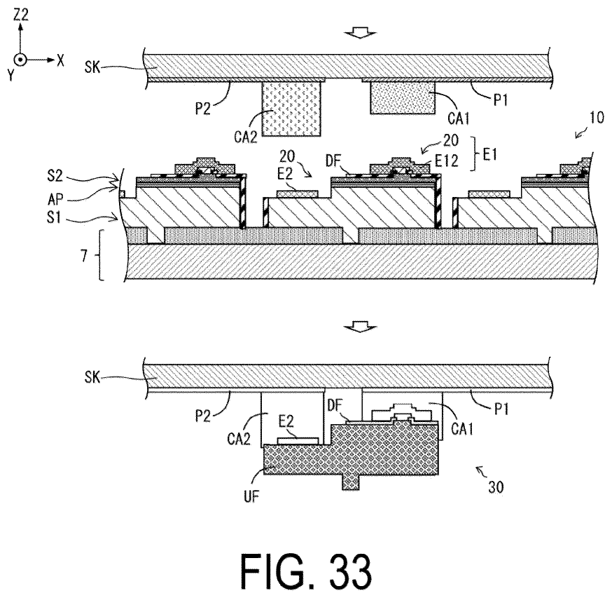

FIG. 31 is a flowchart schematically showing a method for manufacturing a light-emitting element in Example 4. FIG. 32 is a cross-sectional view schematically illustrating a method for manufacturing the light-emitting element in Example 4. FIG. 33 is a cross-sectional view schematically illustrating a method for manufacturing the light-emitting element in Example 4.

As illustrated in FIGS. 31 to 33, the method for manufacturing the light-emitting element in Example 4 includes preparing a semiconductor substrate in which the first type semiconductor portion S1, the active portion AP, and the second type semiconductor portion S2 are formed in this order on the base substrate BK, and forming an insulating film (first insulating film DF1) on a side surface of at least one selected from the group consisting of the first type semiconductor portion S1, the active portion AP, and the second type semiconductor portion S2.

For example, depending on film formation conditions, there is a case where the active portion AP and the second type semiconductor portion S2 are not formed to wrap around the first side surface FS. In Example 4, on the side of the first side surface FS, the first insulating film DF1 covering a side surface of at least one selected from the group consisting of the first type semiconductor portion S1, the active portion AP, and the second type semiconductor portion S2 is formed. The second insulating film DF2 covering the second side surface SS may be formed.

The method for manufacturing the light-emitting element in Example 4 further includes: preparing the support substrate SK; and bonding the light emitter 20 including at least a part of each of the first type semiconductor portion S1, the active portion AP, and the second type semiconductor portion S2 to the support substrate SK via the first bonding material CA1 and the second bonding material CA2, and thus the first type semiconductor portion S1 is positioned higher than the active portion AP.

Parts of the second type semiconductor portion S2, the active portion AP, and the first type semiconductor portion S1 may be engraved by etching or the like to expose a part of the upper surface of the first type semiconductor portion S1. This forms the exposure section ES. An insulating film need not be formed on the third side surface TS. The ridge RJ is formed in the second type semiconductor portion S2. Thereafter, the first electrode E1 and the second electrode E2 are formed.

Next, the layered body LB is split to form the light emitter 20 having a single-sided two-electrode structure. As described above, the method for manufacturing the light-emitting element in Example 4 includes after forming the first insulating film DF1, splitting the active portion AP into a plurality of portions and thus exposing a cross section parallel to the thickness direction of the active portion AP and intersecting the first side surface FS. Then, separating the light emitter 20 from the base substrate BK is performed. The light-emitting element 30 is formed by junction-down mounting the light emitter 20 onto the support substrate SK. In addition, details of each process can be understood with reference to Examples 1 to 3 described above.

When the side surface of the laser body is formed at the time of final chip cutting as in a known case, it is difficult to collectively form the insulating films on the side surfaces of a plurality of laser bodies. On the other hand, in Example 4, it is possible to collectively form the insulating films (in other words, collectively form the insulating films at a wafer level) on the side surfaces of the plurality of light emitters 20 on the base substrate BK.

### Example 5

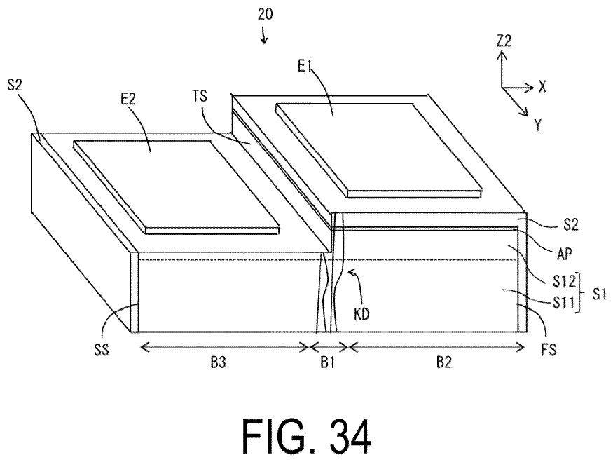

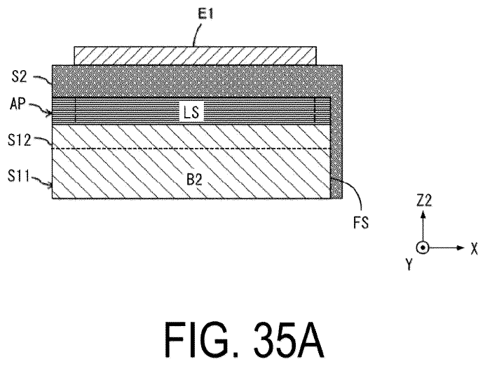

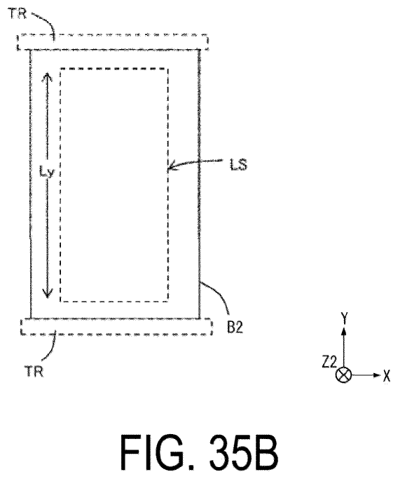

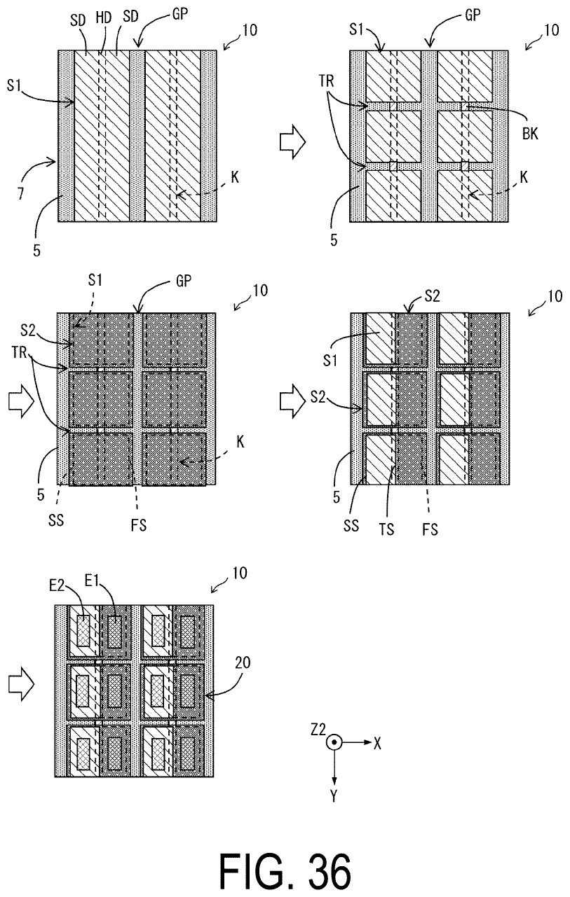

FIG. 34 is a perspective view illustrating the configuration of a light emitter in Example 5. FIG. 35A is a partial cross-sectional view of the light emitter in Example 5. FIG. 35B is a partial plan view of the light emitter in Example 5. FIG. 36 is a plan view schematically illustrating a method for manufacturing a light-emitting element in Example 5.

In the light-emitting element in Example 5, the light emitter 20 may be, for example, a light-emitting diode. As illustrated in FIGS. 34 to 36, the light emitter 20 includes at least a part of each of the first type semiconductor portion S1, the active portion AP, and the second type semiconductor portion S2. The second type semiconductor portion S2 reaches laterally the first type semiconductor portion S1 from above the active portion AP. The second type semiconductor portion S2 may cover at least a part of the first side surface FS of the first type semiconductor portion S1. The active portion AP includes a nitride semiconductor and emits light in the c-axis direction of the active portion AP.

In the method for manufacturing the light-emitting element in Example 5, the plurality of trenches TR may be formed in the first type semiconductor portion S1 after the first type semiconductor portion S1 is formed on the template substrate 7. The first type semiconductor portion S1 may include the base semiconductor portion S11 and the first mold portion S12 including a regrowth layer (e.g., a buffer layer including an n-type GaN-based semiconductor) formed on the base semiconductor portion S11.

In general, when elements are separated by dry etching after the active portion AP is formed, the side surface of the chip may be physically and chemically damaged by ion atoms of the etchant. When the chip size is about 20 μm or less, the ratio of side surface damage to a light-emitting region of the chip increases. Therefore, side surface damage of the active portion AP can become serious.

On the other hand, in Example 5, the trench TR for splitting the first type semiconductor portion S1 is formed before the formation of the active portion AP, and after the formation of the active portion AP, it is not necessary to perform etching for element split. This can enhance the state of the side surfaces of the active portion AP and the second type semiconductor portion S2.

The active portion AP may include a light-emitting section LS, and the entire light-emitting section LS may overlap the second portion B2 (low defect portion SD) in plan view. Since etching damage to the active portion AP is avoided, a size Ly of one side of the light-emitting section LS may be small. The size Ly of one side (e.g., a side orthogonal to the adjacent trench TR) of the light-emitting section LS may be 80 μm or less, 40 μm or less, 20 μm or less, 10 μm or less, or 5 μm or less.

The etching to the first type semiconductor portion S1 is dry etching, and this dry etching may be stopped at the mask portion 5. In this case, the mask portion 5 functions as an etching stopper, and the mask portion 5 is exposed at the bottom of the trench TR. In this case, the etching does not necessarily need to stop at the surface of the mask portion 5 and may stop in the mask portion 5. The mask portion 5 includes a material more difficult to be etched than the first type semiconductor portion S1, and a part of the mask portion 5 may be etched as long as the mask portion 5 plays a role of stopping etching.

When the raw material enters the spaces of the gap GP and the trench TR, the second type semiconductor portion S2 can be formed to reach laterally a side of the first side surface FS in the first type semiconductor portion S1 from above the active portion AP and to reach laterally a side of the second side surface SS. In Example 5, the second type semiconductor portion S2 may be formed to reach laterally a side of the end surface 20F (see FIG. 2) of the light emitter 20 in the first type semiconductor portion S1.

Thereafter, parts of the second type semiconductor portion S2, the active portion AP, and the first type semiconductor portion S1 may be engraved by etching or the like to expose a part of the upper surface of the first type semiconductor portion S1. The third side surface TS need not be covered with the second type semiconductor portion S2. Then, the first electrode E1 and the second electrode E2 are formed. This forms the light emitter 20. The subsequent processes may be the same as those in Example 1 and the like described above.

### Another Configuration Example 5

### (5A)

In another example of Example 5, the layered body LB may be split into the plurality of light emitters 20 by forming the open groove GS after forming the first type semiconductor portion S1, the active portion AP, and the second type semiconductor portion S2. The open groove GS may be formed by cleavage. The open groove GS may be the trench TR formed by etching.

### (5B)

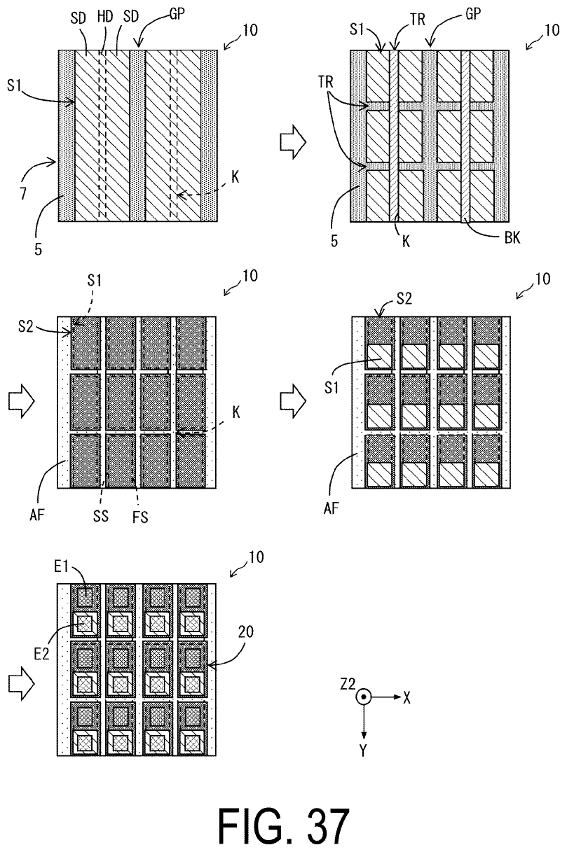

FIG. 37 is a plan view schematically illustrating a method for manufacturing a light-emitting element in another example of Example 5. As illustrated in FIG. 37, a part (dislocation inheritance portion HD) on the opening K in the first type semiconductor portion S1 is removed by at least one of the plurality of trenches TR formed in the first type semiconductor portion S1, and the active portion AP and the second type semiconductor portion S2 are formed on the first type semiconductor portion S1 having the low defect portion SD.

The anchor film AF may be formed, and thus the position of the layered body LB does not change on the template substrate 7 after the active portion AP and the second type semiconductor portion S2 are formed. For example, the anchor film AF is formed on the entire surface by sputtering or an electron beam deposition (EB) method using a resist mask, and then an unnecessary part of the anchor film AF can be lifted off by removing the resist mask.

### (5C)

In Example 5, an LED element in which the light-emitting element 30 emits light in the c-axis direction of the active portion AP has been described as an example, but the present invention is not limited to this, and in another example of Example 5, the light-emitting element 30 may be a semiconductor laser element of a surface emitting type (VCSEL: a vertical cavity surface emitting laser element) that emits light in the c-axis direction of the active portion AP.

### Example 6

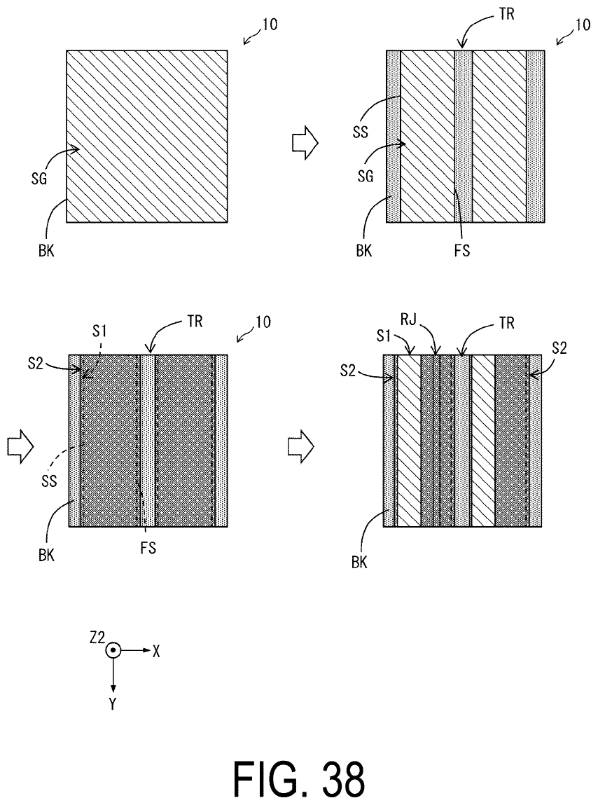

FIG. 38 is a plan view schematically illustrating a method for manufacturing a light-emitting element in Example 6. In Example 1 and the like, the base semiconductor portion S11 is formed by the ELO method. The present invention is not limited to this, and in the method for manufacturing a light-emitting element in one embodiment of the present disclosure, for example, a sapphire substrate may be used as the base substrate BK, and a semiconductor layer containing a nitride semiconductor may be formed in a planar shape above the sapphire substrate. The semiconductor substrate 10 need not include the mask 6 on a GaN substrate.

In the present description, a semiconductor formed by a general method is called a semiconductor SG in order to be distinguished from the base semiconductor portion S11 formed by the ELO method. The semiconductor SG is, for example, a semiconductor layer including a general nitride semiconductor epitaxially grown in the longitudinal direction on a growth substrate.

As illustrated in FIG. 38, for example, a plurality of the semiconductors SG having a bar shape can be formed by removing a part of the semiconductor SG in the semiconductor substrate 10 by etching. The semiconductor SG may be used as the first type semiconductor portion S1, or the first type semiconductor portion S1 including the semiconductor SG and the first mold portion S12 may be formed by appropriately forming the first mold portion S12 on the semiconductor SG. Thus, the first type semiconductor portion S1 includes the first side surface FS.

Next, the active portion AP is formed above the first type semiconductor portion S1. Thereafter, the second type semiconductor portion S2 is formed to reach laterally the first type semiconductor portion S1 from above the active portion AP. When the light emitter 20 is, for example, a laser body, the ridge RJ is formed, and parts of the second type semiconductor portion S2, the active portion AP, and the first type semiconductor portion S1 may be engraved by etching or the like to expose a part of the upper surface of the first type semiconductor portion S1. Then, the first electrode E1 and the second electrode E2 are formed. Subsequent processes can be performed in a manner same as and/or similar to the processes in Example 1 and the like described above. Therefore, detailed description with illustration will be omitted.

The light emitter 20 may be peeled off from the base substrate BK by various methods, for example, a laser lift-off method. A fragile layer (boron nitride) for facilitating mechanical peeling may be formed between the base substrate BK and the semiconductor SG. A sacrificial layer (InGaN) enabling lift-off by photoelectrochemical etching may be formed.

### Supplementary Notes

The invention according to the present disclosure has been described above based on the various drawings and examples. However, the invention according to the present disclosure is not limited to the above-described embodiments and examples. That is, the invention according to the present disclosure can be variously changed within the scope illustrated in the present disclosure, and embodiments obtained by appropriately combining the technical means disclosed in different embodiments and examples are also included in the technical scope of the invention according to the present disclosure. In other words, those skilled in the art can easily make various variations or modifications based on the present disclosure. Note that these variations or modifications are included within the scope of the present disclosure.

### REFERENCE SIGNS

1 Main substrate
5 Mask portion
6 Mask
7 Template substrate
10 Semiconductor substrate
20 Light emitter
30 Light-emitting element
AP Active portion
BK Base substrate
CA Bonding material (conductive bonding material)
CA1 First bonding material (conductive bonding material)
CA2 Second bonding material (conductive bonding material)
DF Insulating film
E1 First electrode
E2 Second electrode
FS First side surface
S1 First type semiconductor portion
S11 Base semiconductor portion
S12 First mold portion
S2 Second type semiconductor portion
SS Second side surface
ST Support body

1. A light-emitting element comprising:
a light emitter comprising a first type semiconductor portion having a first side surface and first type conductivity, an active portion positioned below the first type semiconductor portion, and a second type semiconductor portion having second type conductivity and reaching laterally the first type semiconductor portion from below the active portion;
a conductive bonding material; and
a support body positioned below the light emitter and supporting the light emitter via the conductive bonding material and thus the first type semiconductor portion is positioned higher than the active portion, wherein
the second type semiconductor portion comprises a ridge,
the first type semiconductor portion comprises a wing portion that is closer to the first side surface than a center portion in an a-axis direction of the first type semiconductor portion and is lower in threading dislocation density than the center portion, and
the ridge overlaps the wing portion in plan view.

2. The light-emitting element according to claim 1, wherein the second type semiconductor portion is smaller in thickness than the first type semiconductor portion.

3. The light-emitting element according to claim 1, wherein the second type semiconductor portion is in contact with the first side surface.

4. The light-emitting element according to claim 1, wherein the conductive bonding material comprises a conductive material having at least one selected from the group consisting of heating fluidity, pressure curability, a thermosetting property, and photocurability.

5. The light-emitting element according to claim 1, wherein a part of an edge of the conductive bonding material protrudes from the light emitter in plan view in which the light-emitting element is viewed in a layering direction of the first type semiconductor portion and the active portion.

6. The light-emitting element according to claim 1, wherein the conductive bonding material goes up along the second type semiconductor portion.

7. The light-emitting element according to claim 6, wherein a go-up height of the conductive bonding material exceeds a lower surface level of the first type semiconductor portion.

8. The light-emitting element according to claim 1, wherein the first type semiconductor portion is an n-type semiconductor portion and the second type semiconductor portion is a p-type semiconductor portion.

9. The light-emitting element according to claim 1, wherein the first side surface is one of two side surfaces facing each other in an a-axis direction of the first type semiconductor portion.

10. The light-emitting element according to claim 9, wherein
the first type semiconductor portion comprises a second side surface that is the other of the two side surfaces, and
the second type semiconductor portion reaches laterally a side of the first side surface of the first type semiconductor portion and reaches laterally a side of the second side surface from below the active portion.

11. The light-emitting element according to claim 1, wherein
the first side surface comprises an inclined surface, and
the second type semiconductor portion covers the inclined surface.

12. The light-emitting element according to claim 1, wherein
the active portion comprises a nitride semiconductor, and
the light emitter comprises an optical resonator comprising at least a part of each of the first type semiconductor portion, the active portion, and the second type semiconductor portion, the optical resonator comprising a pair of resonator end surfaces.

13. (canceled)

14. The light-emitting element according to claim 12, wherein
the first type semiconductor portion and the second type semiconductor portion comprise a nitride semiconductor, and
each of the pair of resonator end surfaces is an m-plane of a nitride semiconductor.

15. (canceled)

16. The light-emitting element according to claim 1, wherein
the active portion comprises a nitride semiconductor, and
the light-emitting element emits light in a c-axis direction of the active portion.

17. The light-emitting element according to claim 1, further comprising an insulating film covering a part of the second type semiconductor portion wrapping around the first side surface.

18. The light-emitting element according to claim 1, wherein
the first type semiconductor portion comprises a nitride semiconductor, and
the first side surface comprises a crystal plane.

19. The light-emitting element according to claim 1, wherein the first type semiconductor portion comprises a GaN-based semiconductor.

20. The light-emitting element according to claim 8, wherein
an anode is provided below the second type semiconductor portion, and
a cathode is provided above the first type semiconductor portion.

21. The light-emitting element according to claim 8, wherein
the first type semiconductor portion comprises an exposure section below which the second type semiconductor portion is not positioned,
an anode is provided below the second type semiconductor portion, and
a cathode is provided below the exposure section.

22. (canceled)

23. A method for manufacturing a light-emitting element, the method comprising:
preparing a semiconductor substrate in which a first type semiconductor portion, an active portion, and a second type semiconductor portion are formed in this order on a base substrate;
forming an insulating film on a side surface of at least one selected from the group consisting of the first type semiconductor portion, the active portion, and the second type semiconductor portion;
preparing a support substrate; and
bonding a light emitter comprising at least a part of each of the first type semiconductor portion, the active portion, and the second type semiconductor portion to the support substrate via a conductive bonding material, and thus the first type semiconductor portion is positioned higher than the active portion.

24.-27. (canceled)
